(19) United States
(12) Patent Application Publication
(10) Pub. No.: US 2025/0295011 A1
(43) Pub. Date: Sep. 18, 2025

(54) DISPLAY PANEL AND DISPLAY DEVICE

(71) Applicants: Beijing BOE Technology Development Co., Ltd., Beijing (CN); BOE Technology Group Co., Ltd., Beijing (CN)

(72) Inventors: Dacheng Zhang, Beijing (CN); Chen Xu, Beijing (CN); Chao Pu, Beijing (CN)

(21) Appl. No.: 18/838,484

(22) PCT Filed: Nov. 17, 2023
(86) PCT No.: PCT/CN2023/132374

§ 371 Date: Jun. 9, 2025

(51) Int. Cl. H10K 59/80; H10K 59/121; H10K 59/122; H10K 59/35; H10K 102/00

(52) U.S. Cl. CPC H10K 59/876; H10K 59/1213; H10K 59/122; H10K 59/352; H10K 59/80515; H10K 59/80518; H10K 59/879; H10K 2102/351

(57) ABSTRACT

A display panel and a display device are provided. The display panel includes a base substrate and sub-pixels. A first electrode of a light-emitting element of the sub-pixel includes a reflective layer, a transparent conductive layer, and a dielectric layer between the reflective layer and the transparent conductive layer. A second electrode of the light-emitting element forms a first optical cavity with a portion of the reflective layer in a center region of the first electrode, and forms a second optical cavity with a portion of the reflective layer in an edge region of the first electrode. At least one of the reflective layer, the transparent conductive layer and the dielectric layer has different thicknesses in the center region and in the edge region, such that a cavity length of the first optical cavity is different from that of the second optical cavity.

### CROSS REFERENCE TO RELATED APPLICATION(S)

This application is a Section 371 National Stage Application of International Application No. PCT/CN2023/132374, filed on Nov. 17, 2023, entitled “DISPLAY PANEL AND DISPLAY DEVICE”, which is incorporated herein by reference in its entirety.

### TECHNICAL FIELD

The present disclosure relates to the field of display technology, and in particular, to a display panel and a display device.

### BACKGROUND

Silicon-based organic light-emitting diode (OLED) displays are expected to become the preferred display solution for AR and VR due to their high contrast, high response speed and high PPI. It is difficult for existing silicon-based OLEDs to achieve a luminance meeting the display requirements of AR and VR. In order to enhance the display luminance of the silicon-based OLEDs, a strong microcavity structure is used in the related art to enhance the luminance of the display device. Generally, a microcavity effect of an edge region of a sub-pixel is different from that of a center region of the sub-pixel. In a traditional OLED device, a ratio of an edge region of a sub-pixel to an entire display region of the sub-pixel is small due to a large size of the OLED device, so that the influence of an edge effect may be ignored. In contrast, a silicon-based OLED sub-pixel has an extremely small size, which is, for example, generally in a range of 5 μm to 10 μm, while a mobile phone-sized OLED sub-pixel has a size of tens of micros, and a large-size OLED sub-pixel has a size even more than 100 μm. Such a small size causes the edge region to account for more than 10%. In this case, the difference between the microcavity effect of the edge region of the sub-pixel and the microcavity effect of the center region of the sub-pixel cannot be ignored, leading to a color shift at the edge of the sub-pixel, which seriously affects the display effect.

### SUMMARY

According to an aspect of the present disclosure, a display panel is provided, including a base substrate and a plurality of sub-pixels disposed on the base substrate. The sub-pixel includes: a driving transistor located on the base substrate, the driving transistor having a gate, a source, and a drain; a light-emitting element located on a side of the driving transistor away from the base substrate, the light-emitting element including a first electrode, a second electrode, and a light-emitting material layer between the first electrode and the second electrode, where the first electrode is electrically connected to the source or the drain of the driving transistor, and the first electrode has a center region and an edge region surrounding the center region; and a pixel defining layer, covering a portion of the edge region of the first electrode, where the first electrode includes a reflective layer, a transparent conductive layer, and a dielectric layer located between the reflective layer and the transparent conductive layer, the second electrode and a portion of the reflective layer located in the center region form a first optical cavity, and the second electrode and a portion of the reflective layer located in the edge region form a second optical cavity; and where at least one of the reflective layer, the transparent conductive layer and the dielectric layer has different thicknesses in the center region and in the edge region, such that a cavity length of the first optical cavity is different from a cavity length of the second optical cavity.

For example, the reflective layer of the first electrode has a same thickness in the center region and in the edge region, and at least one of the transparent conductive layer and the dielectric layer of the first electrode has different thicknesses in the center region and in the edge region; and a surface of the second electrode facing the first electrode has a protrusion or a recess, and a projection of the protrusion or the recess on the base substrate at least partially overlaps with a projection of the center region of the first electrode on the base substrate.

For example, the transparent conductive layer of the first electrode has a same thickness in the center region and in the edge region, and the dielectric layer of the first electrode has different thicknesses in the center region and in the edge region.

For example, a surface of the dielectric layer of the first electrode facing the base substrate is substantially parallel to the base substrate, a thickness of the dielectric layer of the first electrode in the center region is smaller than a thickness of the dielectric layer of the first electrode in the edge region, and the surface of the second electrode facing the first electrode has the protrusion, such that the cavity length of the first optical cavity is smaller than the cavity length of the second optical cavity.

For example, a surface of the dielectric layer of the first electrode facing the base substrate is substantially parallel to the base substrate, a thickness of the dielectric layer of the first electrode in the center region is greater than a thickness of the dielectric layer of the first electrode in the edge region, and the surface of the second electrode facing the first electrode has the recess, such that the cavity length of the first optical cavity is greater than the cavity length of the second optical cavity.

For example, the dielectric layer of the first electrode has a same thickness in the center region and in the edge region, and the transparent conductive layer of the first electrode has different thicknesses in the center region and in the edge region.

For example, a surface of the transparent conductive layer of the first electrode facing the base substrate is substantially parallel to the base substrate, a thickness of the transparent conductive layer of the first electrode in the center region is smaller than a thickness of the transparent conductive layer of the first electrode in the edge region, the surface of the second electrode facing the first electrode has the protrusion, and the cavity length of the first optical cavity is smaller than the cavity length of the second optical cavity.

For example, a surface of the transparent conductive layer of the first electrode facing the base substrate is substantially parallel to the base substrate, a thickness of the transparent conductive layer of the first electrode in the center region is greater than a thickness of the transparent conductive layer of the first electrode in the edge region, the surface of the second electrode facing the first electrode has the recess, and the cavity length of the first optical cavity is greater than the cavity length of the second optical cavity.

For example, the transparent conductive layer of the first electrode has a same thickness in the center region and in the edge region, and at least one of the reflective layer and the dielectric layer of the first electrode has different thicknesses in the center region and in the edge region; and a surface of the second electrode facing the first electrode is substantially parallel to the base substrate.

For example, the reflective layer of the first electrode has a same thickness in the center region and in the edge region, and the dielectric layer of the first electrode has different thicknesses in the center region and in the edge region.

For example, a surface of the dielectric layer of the first electrode away from the base substrate is substantially parallel to the base substrate, a thickness of the dielectric layer of the first electrode in the center region is smaller than a thickness of the dielectric layer of the first electrode in the edge region, and the cavity length of the first optical cavity is smaller than the cavity length of the second optical cavity.

For example, a surface of the dielectric layer of the first electrode away from the base substrate is substantially parallel to the base substrate, a thickness of the dielectric layer of the first electrode in the center region is greater than a thickness of the dielectric layer of the first electrode in the edge region, and the cavity length of the first optical cavity is greater than the cavity length of the second optical cavity.

For example, the reflective layer of the first electrode has different thicknesses in the center region and in the edge region, the dielectric layer of the first electrode has different thicknesses in the center region and in the edge region, and for the first electrode, a sum of a thickness of the reflective layer in the center region and a thickness of the dielectric layer in the center region is substantially equal to a sum of a thickness of the reflective layer in the edge region and a thickness of the dielectric layer in the edge region.

For example, a surface of the dielectric layer of the first electrode away from the base substrate and a surface of the reflective layer facing the base substrate are substantially parallel to the base substrate, the thickness of the dielectric layer of the first electrode in the center region is smaller than the thickness of the dielectric layer of the first electrode in the edge region, and the thickness of the reflective layer of the first electrode in the center region is greater than the thickness of the reflective layer of the first electrode in the edge region.

For example, a surface of the dielectric layer of the first electrode away from the base substrate and a surface of the reflective layer facing the base substrate are substantially parallel to the base substrate, the thickness of the dielectric layer of the first electrode in the center region is greater than the thickness of the dielectric layer of the first electrode in the edge region, and the thickness of the reflective layer of the first electrode in the center region is smaller than the thickness of the reflective layer of the first electrode in the edge region.

For example, the dielectric layer includes a first material located in the center region of the first electrode and a second material located in the edge region of the first electrode, and an etching rate of the first material is different from an etching rate of the second material.

For example, one of the first material and the second material is SiNx, and the other of the first material and the second material is SiOx.

For example, an equivalent refractive index of layers in the first optical cavity is different from an equivalent refractive index of layers in the second optical cavity.

For example, the first optical cavity and the second optical cavity satisfies:

$$\vert h 1 - \frac{n λ}{2 N 1} \vert = \frac{λ}{2} , and \vert h 2 - \frac{n λ}{2 N 2} \vert = \frac{λ}{2} ,$$

where h1 represents the cavity length of the first optical cavity, h2 represents the cavity length of the second optical cavity, n is a positive integer, λ represents a central wavelength of light emitted by the sub-pixel, N1 represents an equivalent refractive index of layers in the first optical cavity, and N2 represents an equivalent refractive index of layers in the second optical cavity.

For example, the edge region of the first electrode includes a plurality of nested annular sub-regions, and at least one of the reflective layer, the transparent conductive layer and the dielectric layer has different thicknesses in adjacent annular sub-regions, such that the second electrode and a portion of the reflective layer located in each sub-region form a sub-optical cavity, and adjacent sub-optical cavities have different cavity lengths.

For example, an area of the center region is greater than an area of each annular sub-region, and among the plurality of annular sub-regions, the annular sub-region closer to the center region has a greater area.

For example, the plurality of sub-pixels include a first sub-pixel, a second sub-pixel and a third sub-pixel, and the first sub-pixel, and a color of the first sub-pixel, a color of the second sub-pixel and a color of the third sub-pixel are different from each other,

$$where Src / Sr < Sgc / Sg < Sbc / Sb , and Sr < Sg < Sb ,$$

where Sr, Sg and Sb represent an area of an opening region of the first sub-pixel, an area of an opening region of the second sub-pixel and an area of an opening region of the third sub-pixel respectively, and Src, Sgc and Sbc represent an area of the center region of the first electrode of the first sub-pixel, an area of the center region of the first electrode of the second sub-pixel and an area of the center region of the first electrode of the third sub-pixel respectively, the opening region being a region of the first electrode not covered by the pixel defining layer. For example, 80%<Src/Sr<Sgc/Sg<Sbc/Sb<95%.

For example, among sub-pixels of a same color, the sub-pixel located in a center region of the display panel has an area ratio different from that of the sub-pixel located in an edge region of the display panel, where the area ratio of the sub-pixel is a ratio of an area of the center region of the first electrode of the sub-pixel to an area of an opening region of the sub-pixel.

For example, the edge region of the first electrode includes a first edge region covered by the pixel defining layer and a second edge region not covered by the pixel defining layer, where at least one of the reflective layer, the transparent conductive layer and the dielectric layer has a thickness in the center region different from that in the first edge region and that in the second edge region.

For example, the edge region of the first electrode includes a first edge region covered by the pixel defining layer and a second edge region not covered by the pixel defining layer, where at least one of the reflective layer, the transparent conductive layer and the dielectric layer has a thicknesses in the center region different from that in the second edge region.

For example, the sub-pixel further includes a via hole configured to electrically connect the first electrode to the source or the drain of the driving transistor, where an edge of the center region of the first electrode facing the via hole is spaced apart from an edge of an opening region of the sub-pixel by a first distance; and where an edge of the center region of the first electrode away from the via hole is spaced apart from the edge of the opening region of the sub-pixel by a second distance smaller than the first distance.

For example, in a case that the via hole is located inside the opening region of the sub-pixel, a ratio of the first distance to the second distance is a first ratio; and in a case that the via hole is located outside the opening region of the sub-pixel, a ratio of the first distance to the second distance is a second ratio, the first ratio being greater than the second ratio.

For example, the pixel defining layer includes a covering portion covering first electrodes of adjacent sub-pixels and a non-covering portion located between the first electrodes of the adjacent sub-pixels, where reflective layers of the adjacent sub-pixels are continuous to form a general reflective layer, the general reflective layer includes a first reflective portion located in an opening region and a second reflective portion located outside the opening region, the second reflective portion includes a first sub-portion and a second sub-portion located on opposite sides of the first sub-portion, a projection of the first sub-portion on the base substrate at least partially overlaps with a projection of the non-covering portion of the pixel defining layer on the base substrate, and a projection of the second sub-portion on the base substrate at least partially overlaps with a projection of the covering portion of the pixel defining layer on the base substrate; and where a surface of the first sub-portion of the second reflective portion away from the base substrate and a surface of the second sub-portion away from the base substrate have a first height difference, and a surface of the covering portion of the pixel defining layer away from the base substrate and a surface of the non-covering portion of the pixel defining layer away from the base substrate have a second height difference, a difference between the first height difference and the second height difference being within a preset range.

For example, |ΔDpdl−Δreflect|/Δreflect<5%, where Δreflect represents the first height difference, and ΔDpdl represents the second height difference.

For example, the surface of the non-covering portion of the pixel defining layer away from the base substrate is lower than the surface of the covering portion of the pixel defining layer away from the base substrate; and the surface of the first sub-portion of the second reflective portion away from the base substrate is lower than the surface of the second sub-portion away from the base substrate.

For example, a thickness of the first sub-portion is equal to a thickness of the second sub-portion, and a surface of the first sub-portion close to the base substrate is lower than a surface of the second sub-portion close to the base substrate.

For example, the covering portion of the pixel defining layer has an undercut structure on a side of the covering portion of the pixel defining layer facing the non-covering portion; and a thickness of the first sub-portion of the second reflective portion is smaller than a thickness of the second sub-portion of the second reflective portion, and a surface of the first sub-portion close to the base substrate is substantially flush with a surface of the second sub-portion close to the base substrate.

For example, the surface of the non-covering portion of the pixel defining layer away from the base substrate is lower than a surface of the transparent conductive layer of the first electrode close to the base substrate; and the surface of the first sub-portion away from the base substrate is lower than the surface of the second sub-portion away from the base substrate, and a surface of the first sub-portion close to the base substrate is substantially flush with a surface of the second sub-portion close to the base substrate.

For example, the surface of the non-covering portion of the pixel defining layer away from the base substrate is higher than the surface of the covering portion of the pixel defining layer away from the base substrate; and the surface of the first sub-portion of the second reflective portion away from the base substrate is higher than the surface of the second sub-portion away from the base substrate.

According to another aspect of the present disclosure, a display panel is further provided, including a base substrate and a plurality of sub-pixels disposed on the base substrate. The sub-pixel includes: a driving transistor located on the base substrate, the driving transistor having a gate, a source, and a drain; a light-emitting element located on a side of the driving transistor away from the base substrate, the light-emitting element including a first electrode, a second electrode, and a light-emitting material layer between the first electrode and the second electrode, where the first electrode is electrically connected to the source or the drain of the driving transistor, and the first electrode has a center region and an edge region surrounding the center region; and a pixel defining layer covering at least a portion of the edge region of the first electrode, where the first electrode includes a reflective layer, a transparent conductive layer, and a dielectric layer located between the reflective layer and the transparent conductive layer, the second electrode and a portion of the reflective layer located in the center region form a first optical cavity, and the second electrode and a portion of the reflective layer located in the edge region form a second optical cavity; where output light of the first optical cavity has a first central wavelength 21, and output light of the second optical cavity has a second central wavelength λ2; and where at least one of the reflective layer, the transparent conductive layer and the dielectric layer has different thicknesses in the center region and in the edge region, such that a relative deviation value |1−λ1/λ2| between the first central wavelength λ1 and the second central wavelength λ2 is less than 5%.

For example, the pixel defining layer covers the entire edge region of the first electrode, and at least one of the reflective layer, the transparent conductive layer and the dielectric layer has a thickness in the center region different from that in the entire edge region.

For example, the reflective layer of the first electrode has a same thickness in the center region and in the edge region, and at least one of the transparent conductive layer and the dielectric layer of the first electrode has different thicknesses in the center region and in the edge region; and a surface of the second electrode facing the first electrode has a protrusion or a recess, and a projection of the protrusion or the recess on the base substrate at least partially overlaps with a projection of the center region of the first electrode on the base substrate.

For example, the transparent conductive layer of the first electrode has a same thickness in the center region and in the edge region, and at least one of the reflective layer and the dielectric layer of the first electrode has different thicknesses in the center region and in the edge region; and a surface of the second electrode facing the first electrode is substantially parallel to the base substrate.

According to another aspect of the present disclosure, a display device is further provided, including the display panel in embodiments of the present disclosure.

### BRIEF DESCRIPTION OF THE DRAWINGS

FIG. 1 shows a schematic plan view of a display panel according to an embodiment of the present disclosure.

FIG. 2 shows a cross-sectional view of a sub-pixel in a display panel according to an embodiment of the present disclosure.

FIG. 3 shows a cross-sectional view of a light-emitting element of a sub-pixel according to an embodiment of the present disclosure.

FIG. 4 shows a cross-sectional view of a light-emitting element of a sub-pixel according to another embodiment of the present disclosure.

FIG. 5 shows a cross-sectional view of a light-emitting element of a sub-pixel according to another embodiment of the present disclosure.

FIG. 6 shows a cross-sectional view of a light-emitting element of a sub-pixel according to another embodiment of the present disclosure.

FIG. 7 shows a cross-sectional view of a light-emitting element of a sub-pixel according to another embodiment of the present disclosure.

FIG. 8 shows a cross-sectional view of a light-emitting element of a sub-pixel according to another embodiment of the present disclosure.

FIG. 9 shows a cross-sectional view of a light-emitting element of a sub-pixel according to another embodiment of the present disclosure.

FIG. 10 shows a cross-sectional view of a light-emitting element of a sub-pixel according to another embodiment of the present disclosure.

FIG. 11A shows a cross-sectional view of a light-emitting element of a sub-pixel according to another embodiment of the present disclosure.

FIG. 11B shows a cross-sectional view of a light-emitting element of a sub-pixel according to another embodiment of the present disclosure.

FIG. 12 shows a schematic plan view of a first electrode of a sub-pixel according to an embodiment of the present disclosure.

FIG. 13 shows a schematic plan view of sub-pixels of different colors according to an embodiment of the present disclosure.

FIG. 14 shows a schematic plan view of sub-pixels of the same color according to an embodiment of the present disclosure.

FIG. 15A shows a schematic plan view of a sub-pixel according to an embodiment of the present disclosure.

FIG. 15B shows a schematic plan view of a sub-pixel according to another embodiment of the present disclosure.

FIG. 16A shows a cross-sectional view of a non-display region of a light-emitting element of a sub-pixel according to an embodiment of the present disclosure.

FIG. 16B shows a cross-sectional view of a non-display region of a light-emitting element of a sub-pixel according to another embodiment of the present disclosure.

FIG. 16C shows a cross-sectional view of a non-display region of a light-emitting element of a sub-pixel according to another embodiment of the present disclosure.

FIG. 16D shows a cross-sectional view of a non-display region of a light-emitting element of a sub-pixel according to another embodiment of the present disclosure.

### DETAILED DESCRIPTION OF EMBODIMENTS

In order to make objectives, technical solutions and advantages of the embodiments of the present disclosure clearer, technical solutions of the embodiments of the present disclosure will be clearly and completely described below with reference to the accompanying drawings. Obviously, the described embodiments are just some embodiments rather than all embodiments of the present disclosure. Based on the described embodiments of the present disclosure, all additional embodiments obtained by those of ordinary skill in the art without carrying out any inventive effort fall within the scope of protection of the present disclosure. It should be noted that throughout the accompanying drawings, the same or similar reference numeral represents the same or similar element. In the following description, some specific embodiments are for illustrative purposes only and should not be construed as limiting the present disclosure in any way, but rather as examples of the embodiments of the present disclosure. Conventional structures or configurations will be omitted where confusion in the understanding of the present disclosure may be caused. It should be noted that the shapes and sizes of the components in the drawings do not reflect the actual sizes and scales, but merely for illustrating the embodiments of the present disclosure.

Unless otherwise specified, the technical or scientific terms used in the embodiments of the present disclosure should have the usual meanings understood by those skilled in the art. The terms “first”, “second” and the like used in the embodiments of the present disclosure do not indicate any order, quantity, or importance, but are only used to distinguish different components.

In addition, in the description of the embodiments of the present disclosure, the term “connected” or “connected to” may refer to a direct connection between two components, or may refer to a connection between two components via one or more other components. In addition, the two components may be connected or coupled in a wired or wireless manner.

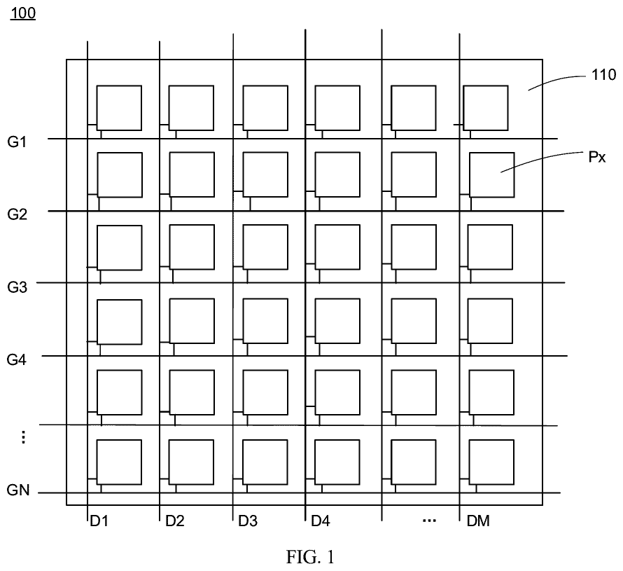

FIG. 1 shows a schematic plan view of a display panel according to an embodiment of the present disclosure.

As shown in FIG. 1, the display panel 100 includes a base substrate 110 and a plurality of sub-pixels Px disposed on the base substrate 110. The plurality of sub-pixels Px are arranged in an array. In FIG. 1, the plurality of sub-pixels Px are arranged into N rows and M columns. A plurality of gate lines G1, G2, . . . . GN electrically connected to the plurality of sub-pixels Px may be further provided in the display panel 100. A plurality of data lines D1, D2, . . . . DM electrically connected to the plurality of sub-pixels Px are further provided in the display panel 100. In FIG. 1, each of N rows of sub-pixels Px is connected to a respective one of the N gate lines G1, G2, . . . . GN, and each of M columns of sub-pixels Px is connected to a respective one of the M data lines D1, D2, . . . . DM. That is, each row of sub-pixels is connected to one gate line, and each column of sub-pixels is connected to one data line. However, the embodiments of the present disclosure are not limited thereto, and the number and connection of the gate lines and the number and connection of the data lines may be selected as desired. For example, each row of sub-pixels may be connected to two gate lines, and the number of the gate lines is twice the row number of the sub-pixels; or every two columns of sub-pixels is connected to one data line, and the number of the data lines is half of the column number of the sub-pixels, or the like.

When working, a gate driver circuit applies gate driving signals to the gate lines G1 to GN to turn on each row of sub-pixels Px, and a source driver circuit applies source driving signals to the data lines D1 to DM to enable the turned-on sub-pixels Px to display based on the applied source driving signals. In some embodiments, a plurality of light-emitting control lines connected to the plurality of sub-pixels may be further provided in the display panel 100, and a light-emitting driver circuit provides light-emitting control signals to the plurality of sub-pixels through the plurality of light-emitting control lines.

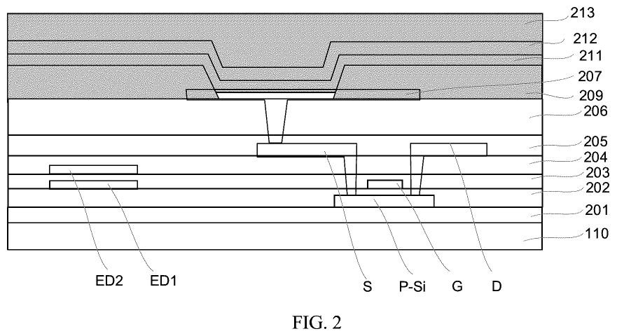

FIG. 2 shows a cross-sectional view of a sub-pixel in a display panel according to an embodiment of the present disclosure.

As shown in FIG. 2, at least one of the plurality of sub-pixels in the display panel includes a driving transistor. The driving transistor has a gate G, a source S, and a drain D. The driving transistor may further include an active layer P—Si located on the base substrate 110, and the gate G is located on a side of the active layer P—Si away from the base substrate 110. The driving transistor may further include a first gate insulation layer 202 between the active layer P—Si and the gate G, a second gate insulation layer 203 located on a side of the gate G away from the base substrate 110, and an interlayer dielectric layer 204 located on a side of the second gate insulation layer 203 away from the base substrate. The source S and the drain D are located on a side of the interlayer dielectric layer 204 away from the base substrate. The sub-pixel may further include a storage capacitor. The storage capacitor includes a first capacitor electrode ED1 and a second capacitor electrode ED2. The first capacitor electrode ED1 and the gate G are arranged in the same layer, and the second capacitor electrode ED2 is arranged between the second gate insulation layer 203 and the interlayer dielectric layer 204.

As shown in FIG. 2, the sub-pixel may further include a light-emitting element located on a side of the driving transistor away from the base substrate 110. The light-emitting element includes a first electrode 207, a second electrode 212, and a light-emitting material layer 211 between the first electrode 207 and the second electrode 212, where the first electrode 207 is electrically connected to the source S or the drain D of the driving transistor. In some embodiments, the first electrode 207 may be an anode, and the second electrode 212 may be a cathode.

In some embodiments, the sub-pixel may further include a pixel defining layer 209. The pixel defining layer 209 covers at least a portion of an edge region of the first electrode 207 to define an opening region. The opening region may corresponds to a portion of the first electrode 207 not covered by the pixel defining layer 207. A portion of a surface of the first electrode 207 away from the base substrate 110 is exposed by the opening region.

In some embodiments, the sub-pixel may further include a planarization layer 206. The planarization layer 206 is located on the side of the interlayer dielectric layer 204 away from the base substrate 110. The first electrode 207 is located on a side of the planarization layer 206 away from the base substrate 110 and passes through the planarization layer 206 to be connected to the source S or the drain D. The pixel defining layer 209 is located on the side of the planarization layer 206 away from the base substrate 110 and partially covers the first electrode 207.

In some embodiments, the sub-pixel may further include a buffer layer 201. The buffer layer 201 is located between the base substrate 110 and the first gate insulation layer 202, and the active layer P—Si of the driving transistor is located between the buffer layer 201 and the first gate insulation layer 202.

In some embodiments, the sub-pixel may further include a passivation layer 205. The passivation layer 205 is located between the planarization layer 206 and the interlayer dielectric layer 204 and covers the source S and the drain D of the driving transistor. The first electrode 207 passes through the interlayer dielectric layer 206 and the passivation layer 205 to be connected to the source S of the driving transistor.

In some embodiments, the sub-pixel may further include an encapsulation layer 213. The encapsulation layer 213 is located on a side of the second electrode 212 away from the base substrate 110. In some embodiments, the encapsulation layer 213 may include a first inorganic encapsulation layer, an organic encapsulation layer and a second inorganic encapsulation layer that are stacked in sequence.

The first electrode 207 may have a multi-layer structure, and the second electrode 212 and a reflective layer in the first electrode 207 form an optical cavity. A cavity length of the optical cavity is a distance between the reflective layer of the first electrode 207 and the second electrode 212 in a direction perpendicular to the base substrate. When the cavity length h of the optical cavity meets the following equation:

$$\vert h - \frac{n λ}{2 N} \vert = \frac{λ}{2} .$$

where h is the cavity length, n is a positive integer, N is the effective refractive index in the microcavity and λ is the central wavelength of the corresponding sub-pixel, the output light of the sub-pixel with the central wavelength λ is enhanced due to constructive interference, that is, the luminance is enhanced.

Generally, the limitation of the manufacturing process on the edge region of the first electrode will cause some difference between an actual cavity length of the edge region and that of the center region, resulting in:

$$\vert {h}^{′} - \frac{n {λ}^{′}}{2 N} \vert = \frac{{λ}^{′}}{2} , {λ}^{′} \neq λ .$$

That is, a central wavelength of the edge region deviates from a central wavelength of the center region, leading to a color shift at the edge of the sub-pixel. For example, the edge of the sub-pixel is reddish, bluish, yellowish, etc., which seriously affecting a display effect of the silicon-based OLEDs.

The embodiments of the present disclosure provide a display panel, including a base substrate and a plurality of sub-pixels disposed on the base substrate. The sub-pixel include: a driving transistor located on the base substrate, the driving transistor having a gate, a source, and a drain; a light-emitting element located on a side of the driving transistor away from the base substrate, the light-emitting element having a first electrode, a second electrode and a light-emitting material layer between the first electrode and the second electrode, where the first electrode is electrically connected to the source or the drain of the driving transistor, and the first electrode has a center region and an edge region surrounding the center region; and a pixel defining layer covering at least a portion of the edge region of the first electrode. The first electrode includes a reflective layer, a transparent conductive layer, and a dielectric layer between the reflective layer and the transparent conductive layer. The second electrode and a portion of the reflective layer located in the center region form a first optical cavity, and the second electrode and a portion of the reflective layer located in the edge region form a second optical cavity. At least one of the reflective layer, the transparent conductive layer and the dielectric layer has different thicknesses in the center region and in the edge region, so that a cavity length of the first optical cavity is different from a cavity length of the second optical cavity.

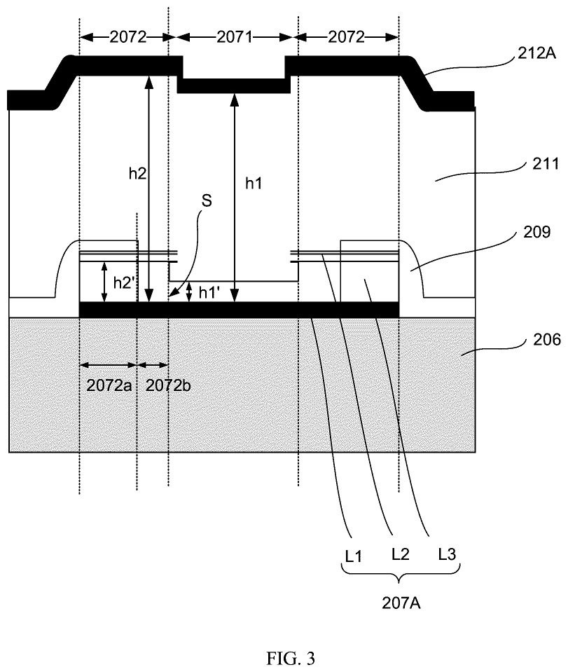

FIG. 3 shows a cross-sectional view of a light-emitting element of a sub-pixel according to an embodiment of the present disclosure.

As shown in FIG. 3, the light-emitting element includes a first electrode 207A, a second electrode 212A, and a light-emitting material layer 211 between the first electrode 207A and the second electrode 212A. The above description for the light-emitting element is also applicable to this embodiment.

The first electrode 207A includes a reflective layer L1, a transparent conductive layer L2, and a dielectric layer L3 between the reflective layer L1 and the transparent conductive layer L2. A material of the transparent conductive layer L2 includes but is not limited to Indium Tin Oxide. The reflective layer L1 may be a single material layer or a composite material layer. A material of each layer of the composite material layer includes but is not limited to Ti, TiN, Al₂O₃, or the like. As shown in FIG. 3, the first electrode 207A has a center region 2071 and an edge region 2072 surrounding the center region 2071. The second electrode 212A and a portion of the reflective layer L1 located in the center region 2071 form a first optical cavity, and a cavity length of the first optical cavity is h1. The second electrode 212A and a portion of the reflective layer L1 located in the edge region 2072 form a second optical cavity, and a cavity length of the second optical cavity is h2.

At least one of the reflective layer L1, the transparent conductive layer L2 and the dielectric layer L3 has different thicknesses in the center region 2071 and in the edge region 2072, so that the cavity length h1 of the first optical cavity is different from the cavity length h2 of the second optical cavity. In some embodiments, the reflective layer L1 has the same thickness in the center region 2071 and in the edge region 2072, and at least one of the transparent conductive layer L2 and the dielectric layer L3 has different thicknesses in the center region 2071 and in the edge region 2072. For example, each of the reflective layer L1 and the transparent conductive layer L2 has the same thickness in the center region 2071 and in the edge region 2072, and the dielectric layer L3 has different thicknesses in the center region 2071 and in the edge region 2072. In the example shown in FIG. 3, a surface of the dielectric layer L3 of the first electrode 207A facing the base substrate is substantially parallel to the base substrate, and a thickness h1′ of the dielectric layer L3 of the first electrode 207A in the center region 2071 is smaller than a thickness h2′ of the dielectric layer L3 in the edge region 2072. That is, the surface of the dielectric layer L3 facing the base substrate is substantially flat, and distances from all positions of the surface to the base substrate are substantially the same, while a surface of the dielectric layer L3 away from the base substrate forms a recess in the center region. Since the transparent conductive layer L2 has the same thickness in the center region 2071 and in the edge region 2072, and the light-emitting material layer 211 is a layer with a uniform thickness, a surface of the second electrode 212A facing the first electrode 207A has a protrusion correspondingly. A projection of the protrusion of the second electrode 212A on the base substrate at least partially overlaps with a projection of the center region 2071 of the first electrode 207A on the base substrate. As shown in FIG. 3, the surface of the second electrode 212A facing the first electrode 207A has a center portion corresponding to the center region 2071 and an edge portion corresponding to the edge region 2072. A height of the center portion of the second electrode 212A relative to the base substrate is smaller than a height of the edge portion of the second electrode 212A relative to the base substrate. In other words, the center portion protrudes towards the base substrate relative to the edge portion. In this way, the cavity length h1 of the first optical cavity being smaller than the cavity length h2 of the second optical cavity is achieved. In some embodiments, the thickness h1′ of the dielectric layer L3 in the center region 2071 and the thickness h2′ of the dielectric layer L3 in the edge region 2072 may be designed so that the first optical cavity and the second optical cavity satisfies:

$$\vert h 1 - \frac{n λ}{2 N 1} \vert = \frac{λ}{2} , \vert h 2 - \frac{n λ}{2 N 2} \vert = \frac{λ}{2} . \qquad ( 1 )$$

where h1 represents the cavity length of the first optical cavity, h2 represents the cavity length of the second optical cavity, n is a positive integer, A represents a central wavelength of light emitted by the sub-pixel, N1 represents an equivalent refractive index of layers in the first optical cavity, and N2 represents an equivalent refractive index of layers in the second optical cavity. The optical cavity includes a plurality of layers each having its own refractive index. The so-called equivalent refractive index here refers to a refractive index of a single layer when the various layers in the optical cavity are equivalent to the single layer. In the example shown in FIG. 3, material of each layer in the first optical cavity is the same as the material of respective layer in the second optical cavity, so that N1=N2. The dielectric layer L3 may be a multi-layer structure including SiOx and/or SiNx, so as to achieve a consistent microcavity effect in the center region and in the edge region. In FIG. 3, the cavity length h2 of the edge region 2072 is greater than the cavity length h1 of the center region 2071, so that the problem that the edge is bluish may be solved.

In some embodiments, output light of the first optical cavity has a first central wavelength λ1, and output light of the second optical cavity has a second central wavelength λ2. In some embodiments, at least one of the reflective layer L1, the transparent conductive layer L2 and the dielectric layer L3 may be designed to have different thicknesses in the center region 2071 and in the edge region 2072, so that a relative deviation value |1−λ1/λ2| between the first central wavelength λ1 and the second central wavelength λ2 is less than 5%.

In the embodiments of the present disclosure, at least one of the reflective layer, the transparent conductive layer and the dielectric layer in the first electrode has different thicknesses in the center region and in the edge region, so that it is possible for the optical cavity between the reflective layer and the second electrode to have different cavity lengths in the edge region and the center region. In this way, a microcavity compensation structure is formed in the edge region of the sub-pixel, so that the sub-pixel in the edge region and the sub-pixel in the center region having different cavity lengths may achieve substantially the same central wavelength λ, thereby alleviating the problem of color shift at the edge of the sub-pixel caused by the edge effect and improving the luminance and the display uniformity of the silicon-based OLED display device.

In some embodiments, as shown in FIG. 3, the pixel defining layer 209 covers a portion but not all of the edge region 2072 of the first electrode 207A, so that a projection of a boundary S between the edge region 2072 and the center region 2071 of the first electrode 207A on the substrate falls outside a projection of the pixel defining layer 209 on the substrate. The edge region 2072 of the first electrode 2072A includes a first edge region 2072a covered by the pixel defining layer 209 and a second edge region 2072b not covered by the pixel defining layer 209. At least one of the reflective layer L1, the transparent conductive layer L2 and the dielectric layer L3 has a thickness in the center region 2071 different from that in the first edge region 2072a and/or in the second edge region 2072b. For example, in FIG. 3, the dielectric layer L3 has a first thickness in the center region 2071, and a second thickness in each of the first edge region 2072a and the second edge region 2072b, the first thickness being different from the second thickness. Of course, the embodiments of the present disclosure are not limited thereto. Taking the dielectric layer L3 as an example again, the dielectric layer L3 may have a first thickness in each of the center region 2071 and the first edge region 2072a and have a second thickness different from the first thickness in the second edge region 2072b. In some other embodiments, the dielectric layer L3 may have a first thickness in the center region 2071, a second thickness in the first edge region 2072a, and a third thickness in the second edge region 2072b, the first thickness, the second thickness and the third thickness being different from each other. The same applies to the reflective layer L1 and the transparent conductive layer L2, which will not be repeated here.

In the related art, although an edge portion of the opening region of the first electrode is theoretically not covered by the pixel defining layer and a cavity length of the edge portion is the same as that of the center region, the color shift may still occur due to a shadow effect of evaporation in practice. In the embodiments of the present disclosure, at least one of the reflective layer, the transparent conductive layer and the dielectric layer has a thickness in the center region different from that in the first edge region and/or that in the second edge region, so that the cavity length in the center region may be different from that in the first edge region and/or that in the second edge region, thereby compensating for the color shift of this portion.

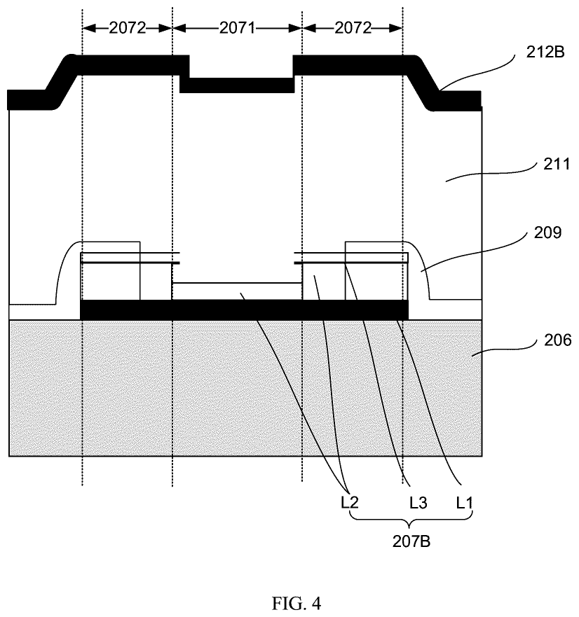

FIG. 4 shows a cross-sectional view of a light-emitting element of a sub-pixel according to another embodiment of the present disclosure. The structure of the light-emitting element in FIG. 4 is similar to that of the light-emitting element in FIG. 3, and the difference is at least in that the material of the dielectric layer in the center region and the material of the dielectric layer in the edge region are different. For ease of description, the following will mainly describe the difference in detail.

As shown in FIG. 4, similarly, the light-emitting element includes a first electrode 207B, a second electrode 212B, and a transparent conductive layer 211 between the first electrode 207B and the second electrode 212B. The first electrode 207B includes a reflective layer L1, a transparent conductive layer L2, and a dielectric layer L3 between the reflective layer L1 and the transparent conductive layer L2. The dielectric layer L3 includes a first material located in the center region 2071 of the first electrode 207B and a second material located in the edge region 2072 of the first electrode 207B. The first material is different from the second material, for example, the first material and the second material may have different etching rates. For example, in FIG. 4, the etching rate of the material (the first material) in the center region of the dielectric layer L3 may be higher than the etching rate of the material (the second material) in the edge region. In this way, due to the difference in the etching rate between the two materials, the etching of the center region and the etching of the edge region may be achieved within one step by adjusting etching parameters, thereby obtaining the structure of the dielectric layer L3 as shown in FIG. 4, in which the thickness of the dielectric layer L3 in the center region 2071 is smaller than the thickness in the edge region 2072. In some embodiments, one of the first material and the second material of the dielectric layer L3 is SiNx, and the other of the first material and the second material is SiOx. For example, in the example shown in FIG. 4, the first material of the dielectric layer L3 is SiNx with a higher etching rate so as to obtain the center portion with smaller thickness, and the second material is SiOx with a lower etching rate so as to obtain the edge portion with greater thickness.

In FIG. 4, the first optical cavity and the second optical cavity may also meet the above equation (1). In some embodiments, N1 #N2 may be achieved by designing materials of layers in the first optical cavity and in the second optical cavity, for example, with the material of the center region of the dielectric layer L3 being different from the material of the edge region of the dielectric layer L3.

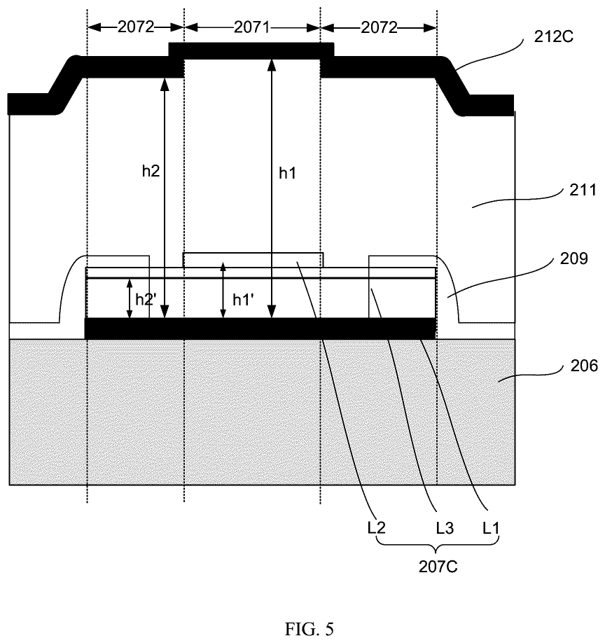

FIG. 5 shows a cross-sectional view of a light-emitting element of a sub-pixel according to another embodiment of the present disclosure. The structure of the light-emitting element in FIG. 5 is similar to that of the light-emitting element in FIG. 3, and the difference is at least in that the first electrode and the second electrode have different structures. For ease of description, the following will mainly describe the difference in detail.

As shown in FIG. 5, similarly, the light-emitting element includes a first electrode 207C, a second electrode 212C, and the transparent conductive layer 211 between the first electrode 207C and the second electrode 212C. The first electrode 207C includes a reflective layer L1, a transparent conductive layer L2, and a dielectric layer L3 between the reflective layer L1 and the transparent conductive layer L2. Different from FIG. 3, the surface of the dielectric layer L3 facing the base substrate is substantially parallel to the base substrate, and the thickness h1′ of the dielectric layer L3 in the center region 2071 is greater than the thickness h2′ of the dielectric layer L3 in the edge region. That is, the surface of the dielectric layer L3 facing the substrate side is substantially flat, and distances from all positions of the surface to the base substrate are substantially the same, while the surface of the dielectric layer L3 away from the base substrate forms a protrusion in the center region. Since the transparent conductive layer L2 has the same thickness in the center region 2071 and in the edge region 2072, and the light-emitting material layer 211 is a layer with a uniform thickness, a surface of the second electrode 212C facing the first electrode 207A also has a recess correspondingly. That is, this surface of the second electrode 212C is recessed towards a direction away from the base substrate, and a projection of the recess on the base substrate at least partially overlaps with the projection of the center region 2071 of the first electrode 207C on the base substrate, as shown in FIG. 5. Accordingly, the cavity length h1 of the first optical cavity being greater than the cavity length h2 of the second optical cavity is achieved. In some embodiments, the thickness h1′ of the dielectric layer L3 in the center region 2071 and the thickness h2′ of the edge region 2072 may be designed so that the first optical cavity and the second optical cavity also meet the above equation (1). For the edge of the sub-pixel being reddish, the structure shown in FIG. 5 may be employed, in which the cavity length h2 of the edge region 2072 is smaller than the cavity length h1 of the center region 2071, so that the problem that the edge of the sub-pixel is reddish may be solved.

In some embodiments, the dielectric layer L3 may have different materials, e.g. materials of different etching rates, in the center region and in the edge region. In the example shown in FIG. 5, the material (the first material) of the dielectric layer L3 in the center region may have an etching rate lower than an etching rate of the material (the second material) in the edge region. In this way, due to the difference in etching rate between the two materials, the etching of the center region and the etching of the edge region may be achieved within one step by adjusting etching parameters, thereby obtaining the structure of the dielectric layer L3 as shown in FIG. 5, in which the thickness of the dielectric layer L3 in the center region 2071 is greater than the thickness in the edge region 2072. In the example as shown in FIG. 5, the first material of the dielectric layer L3 is SiOx with a lower etching rate so as to obtain the center portion with greater thickness; and the second material is SiNx with a higher etching rate so as to obtain the edge portion with smaller thickness.

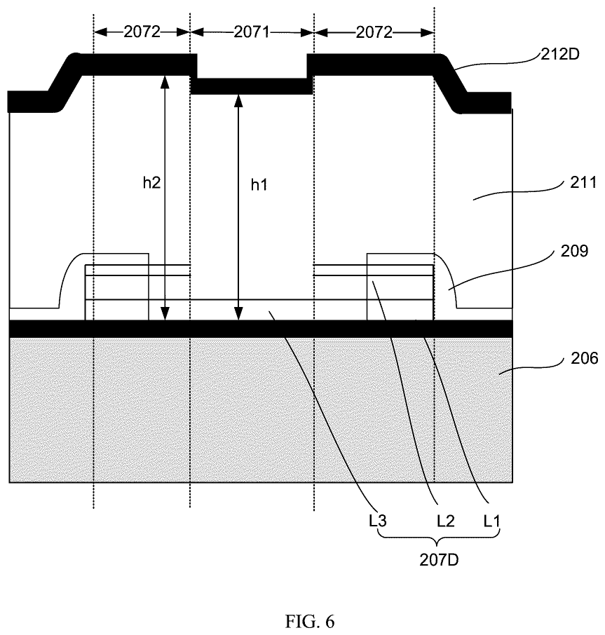

FIG. 6 shows a cross-sectional view of a light-emitting element of a sub-pixel according to another embodiment of the present disclosure. The structure of the light-emitting element in FIG. 6 is similar to that of the light-emitting element in FIG. 3, and the difference is at least in that the first electrode and the second electrode have different structures. For ease of description, the following will mainly describe the difference in detail.

As shown in FIG. 6, similarly, the light-emitting element includes a first electrode 207D, a second electrode 212D, and a transparent conductive layer 211 between the first electrode 207D and the second electrode 212D. The first electrode 207D includes a reflective layer L1, a transparent conductive layer L2, and a dielectric layer L3 between the reflective layer L1 and the transparent conductive layer L2. Different from FIG. 3, each of the reflective layer L1 and the dielectric layer L3 has the same thickness in the center region 2071 and in the edge region 2072 of the first electrode 207D, while the transparent conductive layer L2 has different thicknesses in the center region 2071 and in the edge region 2072 of the first electrode 207D. In the example shown in FIG. 6, the surface of the transparent conductive layer L2 facing the base substrate is substantially parallel to the base substrate, and the thickness of the transparent conductive layer L2 in the center region 2071 is smaller than the thickness of the transparent conductive layer L2 in the edge region 2072. In other words, due to the difference between the thicknesses of the transparent conductive layer L2 in the center region 2071 and the thicknesses of the transparent conductive layer L2 in the edge region 2072, a recess is formed in the surface of the first electrode 207D away from the base substrate in the center region 2071, and due to the uniformity of the thickness of the light-emitting material layer 211, the surface of the second electrode 212D facing the first electrode 207D has a protrusion correspondingly. In this way, the cavity length h1 of the first optical cavity is smaller than the cavity length h2 of the second optical cavity, so that the problem that the edge of sub-pixel is bluish may be solved.

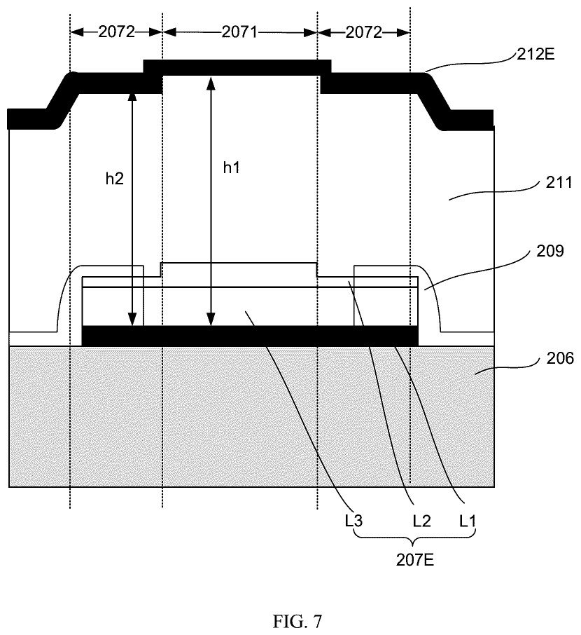

FIG. 7 shows a cross-sectional view of a light-emitting element of a sub-pixel according to another embodiment of the present disclosure. The structure of the light-emitting element in FIG. 7 is similar to that of the light-emitting element in FIG. 6, and the difference is at least in that the structures of the first electrode and the second electrode are different. For ease of description, the following will mainly describe the difference in detail.

As shown in FIG. 7, similarly, the light-emitting element includes a first electrode 207E, a second electrode 212E, and a transparent conductive layer 211 between the first electrode 207E and the second electrode 212E. The first electrode 207E includes a reflective layer L1, a transparent conductive layer L2, and a dielectric layer L3 between the reflective layer L1 and the transparent conductive layer L2. Different from FIG. 6, the surface of the transparent conductive layer L2 facing the base substrate is substantially parallel to the base substrate, and the thickness of the transparent conductive layer L2 in the center region 2701 is greater than the thickness in the edge region 2072. That is, due to the difference between the thicknesses of the transparent conductive layer L2 in the center region 2071 and the thicknesses of the transparent conductive layer L2 in the edge region 2072, a protrusion is formed in the surface of the first electrode 207E away from the substrate in the center region 2071, and due to the uniformity of the thickness of the light-emitting material layer 211, the surface of the second electrode 212E facing the first electrode 207E has a recess correspondingly. In this way, the cavity length h1 of the first optical cavity is greater than the cavity length h2 of the second optical cavity, so that the problem that the edge of sub-pixel is reddish may be solved.

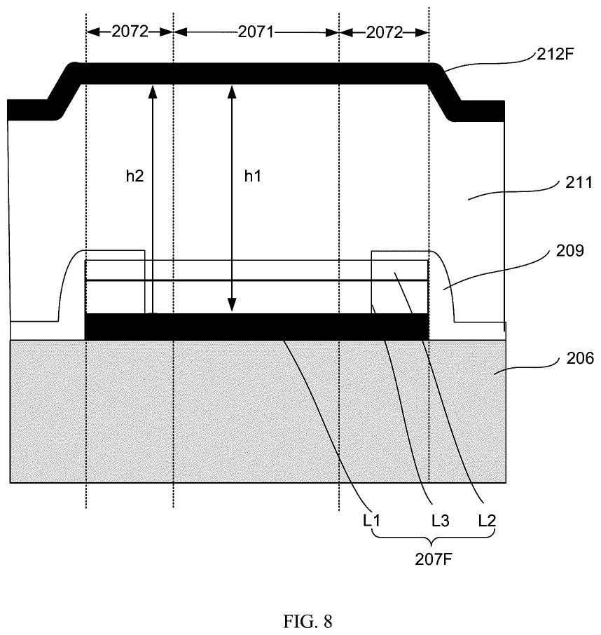

FIG. 8 shows a cross-sectional view of a light-emitting element of a sub-pixel according to another embodiment of the present disclosure. The structure of the light-emitting element in FIG. 8 is similar to that of the light-emitting element in FIG. 3, and the difference is at least in that structures of the first electrode and the second electrode are different. For ease of description, the following will mainly describe the difference in detail.

As shown in FIG. 8, similarly, the light-emitting element includes a first electrode 207F, a second electrode 212F, and a transparent conductive layer 211 between the first electrode 207F and the second electrode 212F. The first electrode 207F includes a reflective layer L1, a transparent conductive layer L2, and a dielectric layer L3 between the reflective layer L1 and the transparent conductive layer L2. Different from FIG. 3, the transparent conductive layer L2 of the first electrode 207F has the same thickness in the center region 2071 and in the edge region 2072 of the first electrode, and at least one of the reflective layer L1 and the dielectric layer L3 may have different thicknesses in the center region 2071 and in the edge region 2072 of the first electrode. For example, the transparent conductive layer L2 has the same thickness in the center region 2071 and in the edge region 2072 of the first electrode, each of the reflective layer L1 and the dielectric layer L3 has different thicknesses in the center region 2071 and in the edge region 2072, and a sum of the thickness of the reflective layer L1 in the center region and the thickness of the dielectric layer L3 in the center region is substantially equal to a sum of the thickness of the reflective layer L1 in the edge region 2072 and the thickness of the dielectric layer L3 in the edge region 2072. In the example shown in FIG. 8, the thickness of the dielectric layer L3 of the first electrode 207F in the center region 2071 is smaller than that in the edge region 2072, the thickness of the reflective layer L1 of the first electrode 207F in the center region 2071 is greater than that in the edge region 2072, and each of the surface of the dielectric layer L3 away from the base substrate and the surface of the reflective layer L1 facing the base substrate is substantially parallel to the base substrate. That is, an upper surface of the reflective layer L1 has a protrusion, and a lower surface of the dielectric layer L3 has a recess matching with the protrusion of the reflective layer L1, so that a combination of the dielectric layer L3 and the reflective layer L1 has a thickness in the center region 2071 consistent with that in the edge region 2072. The transparent conductive layer L2 has the same thickness in the center region 2071 and in the edge region 2072, so that an overall thickness of the first electrode 207F is consistent in the center region and in the edge region. Since the light-emitting material layer 211 is a layer with a uniform thickness, the surface of the second electrode 212F facing the first electrode 207F is substantially parallel to the base substrate, that is, the surface is substantially flat. In this way, the cavity length h1 of the first optical cavity is smaller than the cavity length h2 of the second optical cavity, so that the problem that the edge of sub-pixel is bluish may be solved.

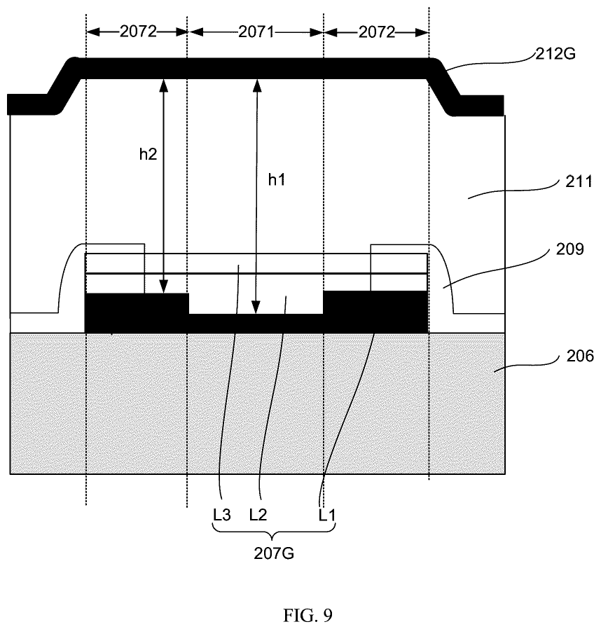

FIG. 9 shows a cross-sectional view of a light-emitting element of a sub-pixel according to another embodiment of the present disclosure. The structure of the light-emitting element in FIG. 9 is similar to that of the light-emitting element in FIG. 8, and the difference is at least in that the first electrode has a different structure. For ease of description, the following will mainly describe the difference in detail.

As shown in FIG. 9, similarly, the light-emitting element includes a first electrode 207G, a second electrode 212G, and a transparent conductive layer 211 between the first electrode 207G and the second electrode 212G. The first electrode 207G includes a reflective layer L1, a transparent conductive layer L2, and a dielectric layer L3 between the reflective layer L1 and the transparent conductive layer L2. Different from FIG. 8, the surface of the dielectric layer L3 of the first electrode 207G away from the base substrate and the surface of the reflective layer L1 facing the base substrate are substantially parallel to the base substrate, the thickness of the dielectric layer L3 in the center region 2071 is greater than that in the edge region 2072, and the thickness of the reflective layer L1 in the center region 2071 is less than that in the edge region 2072. That is, the upper surface of the reflective layer L1 has a recess, and the lower surface of the dielectric layer L3 has a protrusion matching with the recess of the reflective layer L1, so that a thickness of a combination of the dielectric layer L3 and the reflective layer L1 in the center region 2071 is consistent with that in the edge region 2072. The transparent conductive layer L2 has the same thickness in the center region 2071 and in the edge region 2072, so that an overall thickness of the first electrode 207F is consistent in the center region and the edge region. Since the light-emitting material layer 211 is a layer with a uniform thickness, the surface of the second electrode 212F facing the first electrode 207F is substantially parallel to the base substrate, that is, the surface is substantially flat. In this way, the cavity length h1 of the first optical cavity is greater than the cavity length h2 of the second optical cavity, so that the problem that the edge of sub-pixel is reddish may be solved.

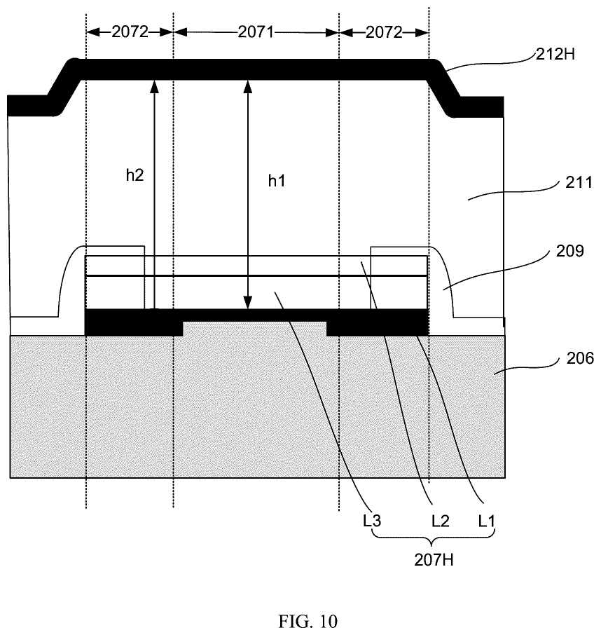

FIG. 10 shows a cross-sectional view of a light-emitting element of a sub-pixel according to another embodiment of the present disclosure. The structure of the light-emitting element in FIG. 10 is similar to that of the light-emitting element in FIG. 8, and the difference is at least in that the first electrode has a different structure. For ease of description, the following will mainly describe the difference in detail.

As shown in FIG. 10, similarly, the light-emitting element includes a first electrode 207H, a second electrode 212H, and a transparent conductive layer 211 between the first electrode 207H and the second electrode 212H. The first electrode 207H includes a reflective layer L1, a transparent conductive layer L2, and a dielectric layer L3 between the reflective layer L1 and the transparent conductive layer L2. Different from FIG. 8, the reflective layer L1 of the first electrode 207H has the same thickness in the center region 2071 and the edge region 2072 of the first electrode, and the dielectric layer L3 of the first electrode 207H has different thicknesses in the center region 2071 and in the edge region 2072 of the first electrode. For example, as shown in FIG. 10, the surface (the upper surface in FIG. 10) of the dielectric layer L3 of the first electrode 207H away from the base substrate is substantially parallel to the base substrate, that is, the surface is substantially flat, and the thickness of the dielectric layer L3 in the center region 2071 is less than that in the edge region 2072. In other words, the upper surface of the dielectric layer L3 is substantially flat, and the lower surface of the dielectric layer L3 is recessed towards a side away from the base substrate in the center region. Since the lower surface of the dielectric layer L3 has the recess and the reflective layer L1 below has the same thickness in the center region 2071 and in the edge region 2072, the reflective layer L1 forms a recess in the center region 2071 correspondingly. The recess is filled with an inorganic layer (e.g., the planarization layer 206) below the reflective layer L1. Since the upper surface of the dielectric layer L3 is substantially flat and the upper transparent conductive layer L2 has the same thickness in the center region 2071 and in the edge region 2072, the upper and lower surfaces of the transparent conductive layer L2 are substantially two parallel flat surfaces. In this way, the cavity length h1 of the first optical cavity is smaller than the cavity length h2 of the second optical cavity, so that the problem that the edge of sub-pixel is bluish may be solved.

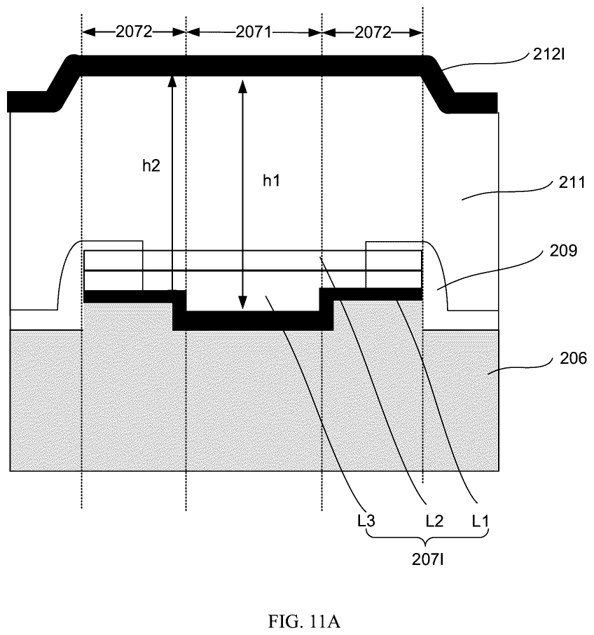

FIG. 11A shows a cross-sectional view of a light-emitting element of a sub-pixel according to another embodiment of the present disclosure. The structure of the light-emitting element in FIG. 11A is similar to that of the light-emitting element in FIG. 10, and the difference is at least in that the first electrode has a different structure. For ease of description, the following will mainly describe the difference in detail.

As shown in FIG. 11A, similarly, the light-emitting element includes a first electrode 207I, a second electrode 212I, and a transparent conductive layer 211 between the first electrode 207I and the second electrode 212I. The first electrode 207I includes a reflective layer L1, a transparent conductive layer L2, and a dielectric layer L3 between the reflective layer L1 and the transparent conductive layer L2. Each of the reflective layer L1 and the transparent conductive layer L2 of the first electrode 207H has the same thickness in the center region 2071 and in the edge region 2072 of the first electrode, and the dielectric layer L3 of the first electrode 207H has different thicknesses in the center region 2071 and in the edge region 2072 of the first electrode. Different from FIG. 10, the surface of the dielectric layer L3 of the first electrode 207I away from the base substrate is substantially parallel to the base substrate, and the thickness of the dielectric layer L3 of the first electrode 207I in the center region 2071 is greater than that in the edge region 2072. In this way, the cavity length h1 of the first optical cavity is greater than the cavity length h2 of the second optical cavity, so that the problem that the edge of the sub-pixel is reddish may be solved.

In the above embodiments, a portion of the edge region of the first electrode is covered by the pixel defining layer. However, the embodiments of the present disclosure are not limited thereto. In some embodiments, the entire edge region of the first electrode is covered by the pixel defining layer. For example, as shown in FIG. 11B, similar to FIG. 11A, the light-emitting element includes a first electrode 207I′, a second electrode 212I′, and a transparent conductive layer 211 between the first electrode 207I′ and the second electrode 212I′. The first electrode 207I′ includes a reflective layer L1, a transparent conductive layer L2, and a dielectric layer L3 between the reflective layer L1 and the transparent conductive layer L2. Each of the reflective layer L1 and the transparent conductive layer L2 of the first electrode 207H has the same thickness in the center region 2071 and in the edge region 2072 of the first electrode, and the dielectric layer L3 of the first electrode 207H has different thicknesses in the center region 2071 and in the edge region 2072 of the first electrode. Different from FIG. 11A, the entire edge region 2072 of the first electrode 207I′ is covered by the pixel defining layer 209. In light-emitting unit of FIG. 11B, it is also possible to achieve the cavity length h1 of the first optical cavity being greater than the cavity length h2 of the second optical cavity, so as to solve the problem that the edge of the sub-pixel is reddish.

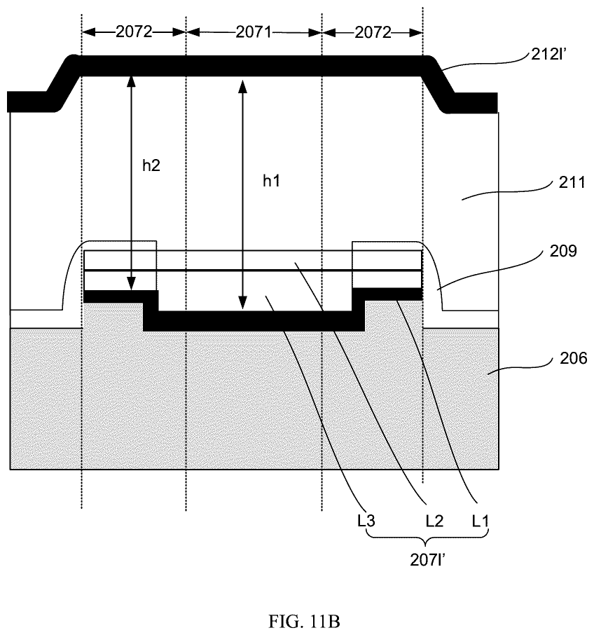

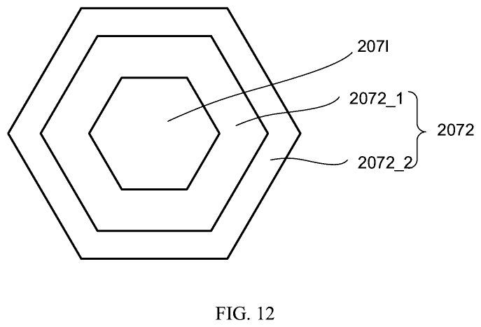

FIG. 12 shows a schematic plan view of a first electrode of a sub-pixel according to an embodiment of the present disclosure.

As shown in FIG. 12, the first electrode includes the center region 2071 and the edge region 2072 surrounding the center region. The description for the center region and the edge region in any of the above embodiments is also applicable to this embodiment. In some embodiments, the edge region 2072 of the first electrode may be configured to include a plurality of nested annular sub-regions, such as sub-regions 2072_1 and 2072_2 as shown in FIG. 12. The sub-region 2072_1 surrounds the center region 2071, and the sub-region 2072_2 surrounds the sub-region 2072_1. Of course, the number of sub-regions is not limited thereto, and more annular sub-regions may be provided as desired. According to the embodiments of the present disclosure, layers in adjacent sub-regions may be arranged like the above described edge region and center region, thereby achieving different microcavity compensation structures in adjacent sub-regions. For example, at least one of the reflective layer, the transparent conductive layer and the dielectric layer may have different thicknesses in adjacent annular sub-regions, so that a portion of the reflective layer in each sub-region forms a sub-optical cavity with the second electrode, and adjacent sub-optical cavities have different cavity lengths. As shown in FIG. 12, adjacent sub-regions 2072_1 and 2072_2 correspond to two optical cavities respectively. Layers of the two optical cavities may be implemented as those of the edge region and the center region of any of the above embodiments, so as to achieve different cavity lengths. In some embodiments, an area of the center region 2071 may be greater than an area of each of the annular sub-regions 2072_1 and 2072_2. Among the plurality of annular sub-regions, the closer an annular sub-region to the center region 2071, the greater an area of this annular sub-region. For example, the sub-region 2072_1 is closer to the center region 2071 than the sub-region 2072_2, thus the area of sub-region 2072_1 is greater than that of sub-region 2072_2. For the outermost sub-region, an area of the sub-region may be calculated based on an area of a portion not covered by the pixel defining layer. In this way, a microcavity effect at an edge of a silicon-based OLED may be finely compensated.

In some embodiments, the center region 2071 and the sub-regions 2072_1 and 2072_2 may have similar outer contours, for example, outer contour of hexagon in FIG. 12. However, the embodiments of the present disclosure are not limited thereto, and outer contours of the center region and the sub-regions may be set as desired.

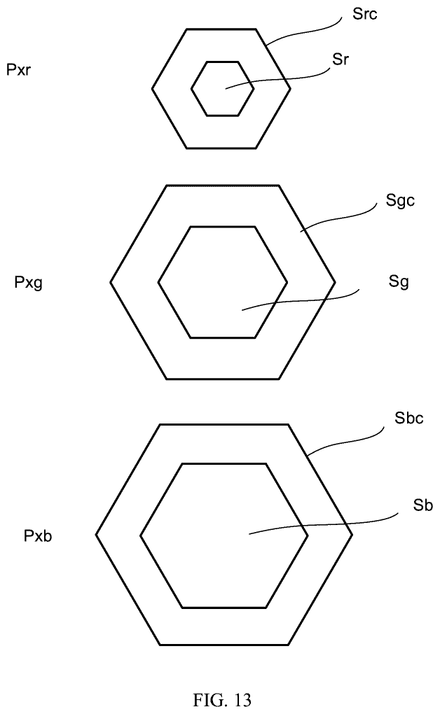

FIG. 13 shows a schematic plan view of sub-pixels of different colors according to an embodiment of the present disclosure.

According to the embodiments of the present disclosure, the plurality of sub-pixels in the display panel may include sub-pixels of different colors, such as a first sub-pixel Pxr, a second sub-pixel Pxg and a third sub-pixel Pxb of different colors. In some embodiments, the first sub-pixel Pxr may be a red sub-pixel, the second sub-pixel Pxg may be a green sub-pixel, and the third sub-pixel Pxb may be a blue sub-pixel. However, the embodiments of the present disclosure are not limited thereto, and the colors of the sub-pixels in the display panel may be designed as desired. As shown in FIG. 13, the first to third sub-pixels satisfies:

$$Src / Sr < Sgc / Sg < Sbc / Sb , and Sr < Sg < S b \qquad ( 2 )$$

where Sr, Sg and Sb represent areas of opening regions of the first subpixel Pxr, the second subpixel Pxg and the third subpixel Pxb respectively, and Src, Sgc and Sbc represent areas of the center regions of the first electrodes of the first subpixel Pxr, the second subpixel Pxg and the third subpixel Pxb respectively.

Referring to the embodiments shown in FIG. 3 to FIG. 11B described above, an area of a portion of the edge region of the first electrode of the sub-pixel not covered by the pixel defining layer may be defined as a compensation area. Then, the compensation area is a difference between an area of the opening region and the area of the center region of the first electrode. The smaller an area of the sub-pixel (i.e., the area of the opening region), the greater the edge effect of the sub-pixel. By configuring the first to third sub-pixels to meet the above relationship (2), a sub-pixel with greater edge effect has a smaller ratio of the area of the center region to the area of the opening region, thereby increasing a ratio of the compensation area to the area of the opening region. Thus, the display uniformity of the display panel may be further improved.

In some embodiments, for the first to third sub-pixels, the ratio of the area of the center region to the area of the opening region may be further limited by: 80%<Src/Sr<Sgc/Sg <Sbc/Sb<95%, so that the display uniformity of the display panel may be further improved.

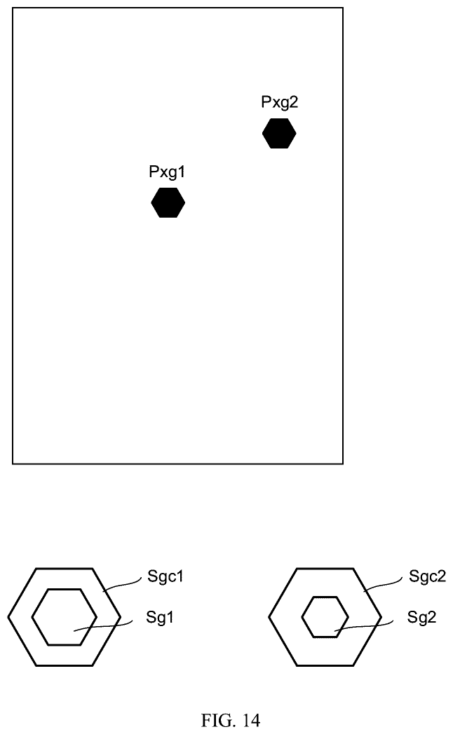

FIG. 14 shows a schematic plan view of sub-pixels of the same color according to an embodiment of the present disclosure.

According to the embodiments of the present disclosure, among sub-pixels of a same color, the sub-pixel located in a center region of the display panel may have an area ratio different from that of the sub-pixel located in an edge region of the display panel, where the area ratio of the sub-pixel is a ratio of an area of the center region of the first electrode of the sub-pixel to an area of an opening region of the sub-pixel. As shown in FIG. 14, taking two green second sub-pixels as an example, a second sub-pixel Pxg1 is closer to the center region of the display panel than a second sub-pixel Pxg2, and it may be considered that the former is located in the center region and the latter is located in the edge region. An area of the opening region of the second sub-pixel Pxg1 is Sg1, and an area of the center region of the first electrode is Sgc1. An area of the opening region of the second sub-pixel Pxg2 is Sg2, and an area of the center region of the first electrode is Sgc2. For example, in a case that an edge effect of the edge region of the display panel is greater than an edge effect of the center region of the display panel, there may be Sgc1/Sg1>Sgc2/Sg2, so that a ratio of the compensation area of the sub-pixel Pxg2 in the edge region to the area of the sub-pixel Pxg2 is greater than a ratio of the compensation area of the sub-pixel Pxg1 in the center region to the area of the sub-pixel Pxg1. Likewise, in a case that the edge effect in the center region of the display panel is greater than the edge effect in the edge region, there may be Sgc1/Sg1<Sgc2/Sg2.

In the embodiments of the present disclosure, for sub-pixels of the same color, the microcavity compensation area ratio of the sub-pixel in the center region is different from the microcavity compensation area ratio of the sub-pixel in the edge region, so that the display uniformity of the center region and the edge region of the display panel may be improved, thereby improving the display effect.

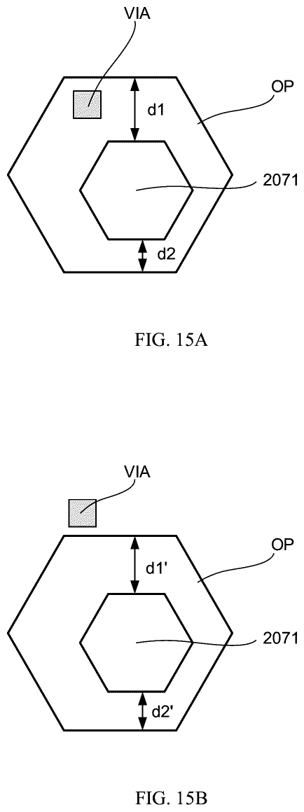

FIG. 15A shows a schematic plan view of a sub-pixel according to an embodiment of the present disclosure. FIG. 15B shows a schematic plan view of a sub-pixel according to another embodiment of the present disclosure.

As shown in FIG. 15A and FIG. 15B, the sub-pixel may further include a via hole VIA configured to electrically connect the first electrode to the source or the drain of the driving transistor. The via hole VIA may be located inside the opening region of the sub-pixel (as shown in FIG. 15A), or may be located outside the opening region of the sub-pixel (as shown in FIG. 15B).

As shown in FIG. 15A, an edge of the center region 2071 of the first electrode facing the via hole VIA is spaced apart from an edge of the opening region OP of the sub-pixel by a first distance d1, and an edge of the center region 2071 of the first electrode away from the via hole VIA is spaced apart from an edge of the opening region OP of the sub-pixel by a second distance d2, the second distance d2 being smaller than the first distance d1, that is, d1>d2. Likewise, as shown in FIG. 15B, a side of the center region 2071 of the first electrode facing the via hole is spaced apart from the opening region OP by a distance d1′, and a side of the center region 2071 away from the via hole is spaced apart from the opening region OP by a distance d2′, where d1′>d2′.

Generally, the first electrode will be uneven on a side of the first electrode close to the via hole, resulting in a more serious edge effect. In the embodiments of the present disclosure, distance between the side of the center region of the first electrode close to the via hole and an edge of the opening region is greater than the distance between the side of the center region away from the via hole and the edge of the opening region, so that it is possible to further improve the display uniformity of a sub-pixel region.

In some embodiments, in the case that the via hole is located inside the opening region of the sub-pixel, as shown in FIG. 15A, a first ratio of the first distance to the second distance is d1/d2. In the case that the via hole is located outside the opening region of the sub-pixel, as shown in FIG. 15B, a second ratio of the first distance to the second distance is d1′/d2′. The first ratio may be greater than the second ratio, that is, d1/d2>d1′/d2′. As compared with the edge effect of the display region when the via is located outside the opening region, the edge effect of the display region when the via is located inside the opening region will be greater. According to the embodiments of the present disclosure, by configuring d1/d2>d1′/d2′, it is possible to ensure the display uniformity of sub-pixels having via holes located at different positions.

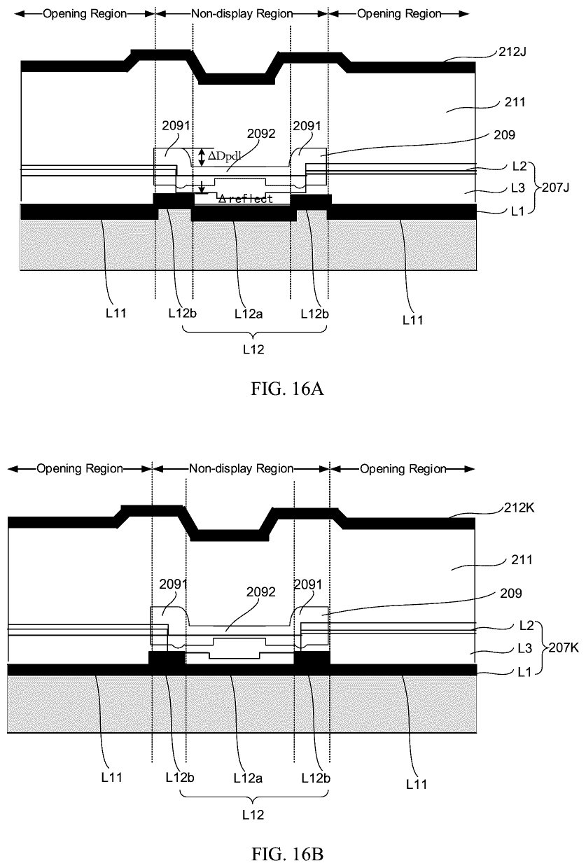

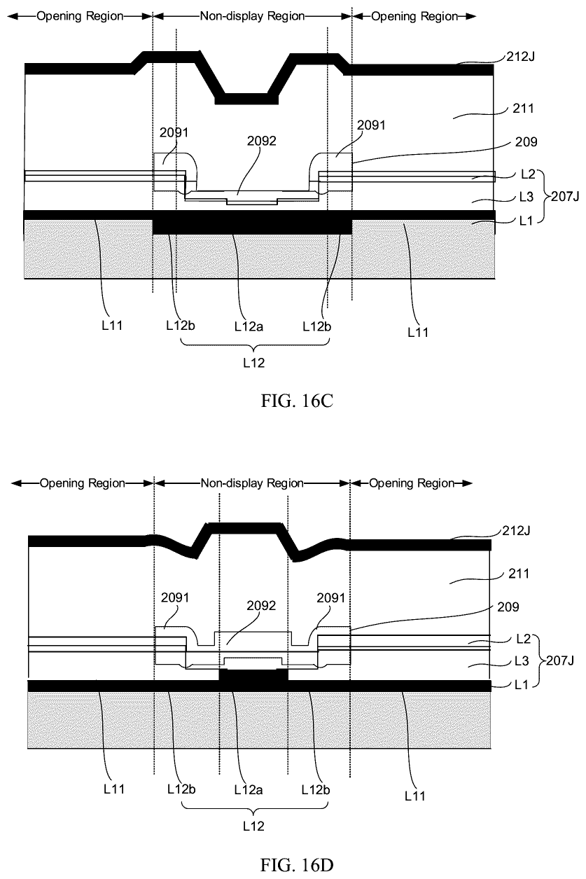

According to the embodiments of the present disclosure, a microcavity compensation design similar to that in the opening region (i.e., the region not covered by the pixel defining layer, also referred to as the display region) in the above-mentioned embodiments may be employed in a non-display region (i.e., the region covered by the pixel defining layer). This will be described in detail below with reference to FIG. 16A to FIG. 16D.

FIG. 16A shows a cross-sectional view of a non-display region of a light-emitting element of a sub-pixel according to an embodiment of the present disclosure.

As shown in FIG. 16A, the pixel defining layer 209 covers edges of the first electrodes 207J of two sub-pixels adjacent to each other. The pixel defining layer 209 may include a covering portion 2091 covering the first electrodes of the adjacent sub-pixels and a non-covering portion 2092 between the first electrodes of the adjacent sub-pixels. As shown in FIG. 16A, the reflective layers L1 of the adjacent sub-pixels are continuous, so as to form a general reflective layer including a first reflective portion L11 located in the opening region and a second reflective portion L12 located outside the opening region (i.e., located in the non-display region). The second reflective portion L12 has a first sub-portion L12a and second sub-portions L12b located at opposite sides of the first sub-portion L12a. A projection of the first sub-portion L12a on the base substrate at least partially overlaps with a projection of the non-covering portion 2092 of the pixel defining layer 209 on the base substrate, and a projection of the second sub-portions L12b on the base substrate at least partially overlaps with a projection of the covering portion 2091 of the pixel defining layer 209 on the base substrate.

For example, in the example shown in FIG. 16A, a surface of the non-covering portion 2092 of the pixel defining layer 209 away from the base substrate is lower than a surface of the covering portion 2091 of the pixel defining layer 209 away from the base substrate. A surface of the first sub-portion L12a of the second reflective portion L12 away from the base substrate is lower than a surface of the second sub-portion L12b away from the base substrate. In some embodiments, the first sub-portion L12a and the second sub-portion L12b of the second reflective portion L12 may have the same thickness, and a surface of the first sub-portion L12a close to the base substrate is also lower than a surface of the second sub-portion L12b close to the base substrate.

As shown in FIG. 16A, a first height difference between the surface of the first sub-portion L12a of the second reflective portion L12 away from the base substrate and the surface of the second sub-portion L12b away from the base substrate is Δreflect, and a second height difference between the surface of the covering portion 2091 of the pixel defining layer 209 away from the base substrate and the surface of the non-covering portion 2092 of the pixel defining layer 209 away from the base substrate is ΔDpdl. A difference between the first height difference Δreflect and the second height difference ΔDpdl is within a preset range. For example, the first height difference Δreflect and the second height difference ΔDpdl may meet the following relationship:

$$\vert Δ Dpdl - Δ reflect \vert / Δ reflect < 5 \% \qquad ( 3 )$$

where Δreflect represents the first height difference, and ΔDpdl represents the second height difference.

The pixel defining layer in the non-display region is also one of the important factors causing the edge effect. According to the embodiments of the present disclosure, the difference between the height difference Δreflect between the upper surface of the reflective layer in the center region and the upper surface of the reflective layer in the non-display region and the height difference ΔDpdl of the upper surface of the pixel defining layer is maintained within a certain range, so that the impact of the microcavity difference caused by the edge effect on the display uniformity may be effectively eliminated.

According to the embodiments of the present disclosure, recess and/or protrusion substantially consistent with that of the pixel defining layer may be provided in the inorganic layer below the reflective layer, so that the consistency of the thickness of the reflective layer may be ensured. The reflective layer is manufactured within one process, thereby improving the uniformity of reflectivity. Of course, the reflective layer may have varied thickness so that the surface of the reflective layer is consistent with that of the pixel defining layer.

For example, in FIG. 16B, the covering portion 2091 of the pixel defining layer 209 may have an undercut structure on a side of the covering portion 2091 facing the non-covering portion, a thickness of the first sub-portion L12a of the second reflecting portion L12 is less than a thickness of the second sub-portion L12b of the second reflecting portion L12, and a surface of the first sub-portion L11 close to the base substrate is substantially flush with a surface of the second sub-portion L12 close to the base substrate. In this way, the second reflecting portion L12 has a structure of recess and protrusion substantially the same as that of the pixel defining layer above the second reflecting portion L12.

In FIG. 16C, the pixel defining layer 209 is formed above a groove of the planarization layer 206, and the surface of the non-covering portion 2092 of the pixel defining layer 209 away from the base substrate is lower than a surface of the transparent conductive layer L2 of the first electrode 207J close to the base substrate. The surface of the first sub-portion L12a of the second reflective portion L12 away from the base substrate is lower than the surface of the second sub-portion L12b away from the base substrate. Here, the so-called “lower” refers to a smaller distance relative to the base substrate. The surface of the first sub-portion L12a close to the base substrate is substantially flush with the surface of the second sub-portion L12b close to the base substrate. In this way, the second reflective portion L12 and the pixel defining layer above the second reflective portion L12 have substantially the same structure of recess and protrusion.

In FIG. 16D, the pixel defining layer is a columnar structure, and the surface of the non-covering portion 2092 of the pixel defining layer 209 away from the base substrate is higher than the surface of the covering portion 2091 of the pixel defining layer 209 away from the base substrate. The surface of the first sub-portion L12a of the second reflective portion L12 away from the base substrate is higher than the surface of the second sub-portion L12b away from the base substrate. The surface of the first sub-portion L12a close to the base substrate may be substantially flush with the surface of the second sub-portion L12b close to the base substrate. In this way, the second reflective portion L12 and the pixel defining layer above the second reflective portion L12 have substantially the same structure of recess and protrusion.

According to the embodiments of the present disclosure, for different structures of the pixel defining layer, the reflective layer is set to be complementary to the pixel defining layer in respective regions, so that the surface of the reflective layer fluctuates in the same manner as the surface the pixel defining layer, thereby reducing the impact of the edge effect on the microcavity effect and improving the display uniformity.

The embodiments of the present disclosure further provide a display device, including the display panel in any of the embodiments mentioned above.

The display device according to the embodiments of the present disclosure may be an electronic device having a display function, such as, but not limited to a smart phone, a mobile phone, a video phone, an e-book reader, a desktop computer (PC), a laptop PC, a netbook PC, a personal digital assistant (PDA), a portable multimedia player (PMP), a digital audio player, a mobile medical device, a camera, a wearable device (such as a head-mounted device, an electronic clothing, an electronic bracelet, an electronic necklace, an electronic accessory, an electronic tattoo, or a smart watch), etc. The display device according to the embodiments of the present disclosure may also be an AR/VR display device, such as a helmet display, stereoscopic display glasses, a glasses-type display, etc. The display device according to the embodiments of the present disclosure may also be a near-eye device that uses a digital display to replace an optical structure, such as an electronic telescope, an electronic microscope, a medical endoscope, and other professional equipment with similar near-eye display requirements.

The electronic device according to the embodiments of the present disclosure may also be a smart home appliance including a display function. For example, the smart home appliance may be a television, a digital video disc (DVD) player, a stereo, a refrigerator, an air conditioner, a vacuum cleaner, an oven, a microwave oven, a washing machine, a dryer, an air purifier, a set-top box, a television (TV) box, a game console, an electronic dictionary, an electronic key, a video recorder, an electronic photo frame, etc.

The electronic device according to the embodiments of the present disclosure may also be a medical device (such as a magnetic resonance angiography (MRA) device, a magnetic resonance imaging (MRI) device, a computed tomography (CT) device, an imaging device, or an ultrasound device), a navigation device, a global positioning system (GPS) receiver, an event data recorder (EDR), a flight data recorder (FDR), an automobile infotainment device, a marine electronic device (such as a marine navigation device, a gyroscope, or a compass), an avionics device, a security device, an industrial or consumer robot, an automatic teller machine (ATM), a point of sale (POS), etc.

The electronic device according to the embodiments of the present disclosure may also be furniture including a display function, a part of a building/structure, an electronic bulletin board, an electronic signature receiving device, a projector, various measuring devices (such as a water meter, an electricity meter, a gas meter, or an electromagnetic wave measuring device), etc. An electronic device according to some embodiments may be any combination of the devices mentioned above. In addition, the electronic device according to the various embodiments may be a flexible device. In addition, it should be clear to those skilled in the art that the electronic device according to the various embodiments of the present disclosure are not limited to the devices mentioned above.

Although in the above embodiments, the layout and layer structure of sub-pixels in the display panel are described by taking a specific layer structure as an example, the embodiments of the present disclosure are not limited thereto. Sub-pixels in the display panel may be distributed in any suitable manner as desired, and each sub-pixel may have other layer structures as desired, as long as the driving transistor of the sub-pixel is capable of driving the light-emitting element to emit light.

1. A display panel, comprising a base substrate and a plurality of sub-pixels disposed on the base substrate, wherein the sub-pixel comprises:
a driving transistor located on the base substrate, the driving transistor having a gate, a source, and a drain;
a light-emitting element located on a side of the driving transistor away from the base substrate, the light-emitting element comprising a first electrode, a second electrode, and a light-emitting material layer between the first electrode and the second electrode, wherein the first electrode is electrically connected to the source or the drain of the driving transistor, and the first electrode has a center region and an edge region surrounding the center region; and
a pixel defining layer covering a portion of the edge region of the first electrode,
wherein the first electrode comprises a reflective layer, a transparent conductive layer, and a dielectric layer located between the reflective layer and the transparent conductive layer, the second electrode and a portion of the reflective layer located in the center region form a first optical cavity, and the second electrode and a portion of the reflective layer located in the edge region form a second optical cavity; and
wherein at least one of the reflective layer, the transparent conductive layer and the dielectric layer has different thicknesses in the center region and in the edge region, such that a cavity length of the first optical cavity is different from a cavity length of the second optical cavity.

2. The display panel according to claim 1,
wherein the reflective layer of the first electrode has a same thickness in the center region and in the edge region, and at least one of the transparent conductive layer and the dielectric layer of the first electrode has different thicknesses in the center region and in the edge region; and
wherein a surface of the second electrode facing the first electrode has a protrusion or a recess, and a projection of the protrusion or the recess on the base substrate at least partially overlaps with a projection of the center region of the first electrode on the base substrate.

3. The display panel according to claim 2, wherein the transparent conductive layer of the first electrode has a same thickness in the center region and in the edge region, and the dielectric layer of the first electrode has different thicknesses in the center region and in the edge region.

4. The display panel according to claim 3, wherein a surface of the dielectric layer of the first electrode facing the base substrate is substantially parallel to the base substrate, a thickness of the dielectric layer of the first electrode in the center region is smaller than a thickness of the dielectric layer of the first electrode in the edge region, and the surface of the second electrode facing the first electrode has the protrusion, such that the cavity length of the first optical cavity is smaller than the cavity length of the second optical cavity.

5. The display panel according to claim 3, wherein a surface of the dielectric layer of the first electrode facing the base substrate is substantially parallel to the base substrate, a thickness of the dielectric layer of the first electrode in the center region is greater than a thickness of the dielectric layer of the first electrode in the edge region, and the surface of the second electrode facing the first electrode has the recess, such that the cavity length of the first optical cavity is greater than the cavity length of the second optical cavity.

6. The display panel according to claim 2, wherein the dielectric layer of the first electrode has a same thickness in the center region and in the edge region, and the transparent conductive layer of the first electrode has different thicknesses in the center region and in the edge region.

7. The display panel according to claim 6, wherein a surface of the transparent conductive layer of the first electrode facing the base substrate is substantially parallel to the base substrate, a thickness of the transparent conductive layer of the first electrode in the center region is smaller than a thickness of the transparent conductive layer of the first electrode in the edge region, the surface of the second electrode facing the first electrode has the protrusion, and the cavity length of the first optical cavity is smaller than the cavity length of the second optical cavity; or
wherein a surface of the transparent conductive layer of the first electrode facing the base substrate is substantially parallel to the base substrate, a thickness of the transparent conductive layer of the first electrode in the center region is greater than a thickness of the transparent conductive layer of the first electrode in the edge region, the surface of the second electrode facing the first electrode has the recess, and the cavity length of the first optical cavity is greater than the cavity length of the second optical cavity.

8. (canceled)

9. The display panel according to claim 1, wherein the transparent conductive layer of the first electrode has a same thickness in the center region and in the edge region, and at least one of the reflective layer and the dielectric layer of the first electrode has different thicknesses in the center region and in the edge region; and
wherein a surface of the second electrode facing the first electrode is substantially parallel to the base substrate.

10. The display panel according to claim 9, wherein the reflective layer of the first electrode has a same thickness in the center region and in the edge region, and the dielectric layer of the first electrode has different thicknesses in the center region and in the edge region;
wherein:
a surface of the dielectric layer of the first electrode away from the base substrate is substantially parallel to the base substrate, a thickness of the dielectric layer of the first electrode in the center region is smaller than a thickness of the dielectric layer of the first electrode in the edge region, and the cavity length of the first optical cavity is smaller than the cavity length of the second optical cavity; or
a surface of the dielectric layer of the first electrode away from the base substrate is substantially parallel to the base substrate, a thickness of the dielectric layer of the first electrode in the center region is greater than a thickness of the dielectric layer of the first electrode in the edge region, and the cavity length of the first optical cavity is greater than the cavity length of the second optical cavity.

11. (canceled)

12. (canceled)

13. The display panel according to claim 9, wherein the reflective layer of the first electrode has different thicknesses in the center region and in the edge region, the dielectric layer of the first electrode has different thicknesses in the center region and in the edge region, and a sum of a thickness of the reflective layer in the center region and a thickness of the dielectric layer in the center region is substantially equal to a sum of a thickness of the reflective layer in the edge region and a thickness of the dielectric layer in the edge region;
wherein:
a surface of the dielectric layer of the first electrode away from the base substrate and a surface of the reflective layer facing the base substrate are substantially parallel to the base substrate, the thickness of the dielectric layer of the first electrode in the center region is smaller than the thickness of the dielectric layer of the first electrode in the edge region, and the thickness of the reflective layer of the first electrode in the center region is greater than the thickness of the reflective layer of the first electrode in the edge region; or
a surface of the dielectric layer of the first electrode away from the base substrate and a surface of the reflective layer facing the base substrate are substantially parallel to the base substrate, the thickness of the dielectric layer of the first electrode in the center region is greater than the thickness of the dielectric layer of the first electrode in the edge region, and the thickness of the reflective layer of the first electrode in the center region is smaller than the thickness of the reflective layer of the first electrode in the edge region.

14. (canceled)

15. (canceled)

16. The display panel according to claim 1, wherein the dielectric layer comprises a first material located in the center region of the first electrode and a second material located in the edge region of the first electrode, and an etching rate of the first material is different from an etching rate of the second material;
wherein one of the first material and the second material is SiNx, and the other of the first material and the second material is SiOx;
wherein an equivalent refractive index of layers in the first optical cavity is different from an equivalent refractive index of layers in the second optical cavity.

17. (canceled)

18. (canceled)

19. The display panel according to claim 1, wherein the first optical cavity and the second optical cavity satisfies:
$$\vert h 1 - \frac{n λ}{2 N 1} \vert = \frac{λ}{2} , and \vert h 2 - \frac{n λ}{2 N 2} \vert = \frac{λ}{2} ,$$
where h1 represents the cavity length of the first optical cavity, h2 represents the cavity length of the second optical cavity, n is a positive integer, λ represents a central wavelength of light emitted by the sub-pixel, N1 represents an equivalent refractive index of layers in the first optical cavity, and N2 represents an equivalent refractive index of layers in the second optical cavity;
wherein the edge region of the first electrode comprises a plurality of nested annular sub-regions, and at least one of the reflective layer, the transparent conductive layer and the dielectric layer has different thicknesses in adjacent annular sub-regions, such that the second electrode and a portion of the reflective layer located in each sub-region form a sub-optical cavity, and adjacent sub-optical cavities have different cavity lengths;
wherein an area of the center region is greater than an area of each annular sub-region, and among the plurality of annular sub-regions, the annular sub-region closer to the center region has a greater area.

20. (canceled)

21. (canceled)

22. The display panel according to claim 1, wherein the plurality of sub-pixels comprise a first sub-pixel, a second sub-pixel and a third sub-pixel, and a color of the first sub-pixel, a color of the second sub-pixel and a color of the third sub-pixel are different from each other,
$$wherein Src / Sr < Sgc / Sg < Sbc / Sb , and Sr < Sg < Sb ,$$
where Sr, Sg and Sb represent an area of an opening region of the first sub-pixel, an area of an opening region of the second sub-pixel and an area of an opening region of the third sub-pixel respectively, and Src, Sgc and Sbc represent an area of the center region of the first electrode of the first sub-pixel, an area of the center region of the first electrode of the second sub-pixel and an area of the center region of the first electrode of the third sub-pixel respectively, the opening region being a region of the first electrode not covered by the pixel defining layer,
$$wherein 80 \% < Src / Sr < Sgc / Sg < Sbc / Sb < 95 \% .$$

23. (canceled)

24. The display panel according to claim 1, wherein among sub-pixels of a same color, the sub-pixel located in a center region of the display panel has an area ratio different from that of the sub-pixel located in an edge region of the display panel, wherein the area ratio of the sub-pixel is a ratio of an area of the center region of the first electrode of the sub-pixel to an area of an opening region of the sub-pixel;
wherein the edge region of the first electrode comprises a first edge region covered by the pixel defining layer and a second edge region not covered by the pixel defining layer, wherein at least one of the reflective layer, the transparent conductive layer and the dielectric layer has a thickness in the center region different from that in the first edge region and that in the second edge region, or has a thicknesses in the center region different from that in the second edge region;
wherein the sub-pixel further comprises a via hole configured to electrically connect the first electrode to the source or the drain of the driving transistor, an edge of the center region of the first electrode facing the via hole is spaced apart from an edge of an opening region of the sub-pixel by a first distance, and an edge of the center region of the first electrode away from the via hole is spaced apart from the edge of the opening region of the sub-pixel by a second distance smaller than the first distance;
wherein in a case that the via hole is located inside the opening region of the sub-pixel, a ratio of the first distance to the second distance is a first ratio; and in a case that the via hole is located outside the opening region of the sub-pixel, a ratio of the first distance to the second distance is a second ratio, the first ratio being greater than the second ratio.

25. (canceled)

26. (canceled)

27. (canceled)

28. (canceled)

29. The display panel according to claim 1, wherein the pixel defining layer comprises a covering portion covering first electrodes of adjacent sub-pixels and a non-covering portion located between the first electrodes of the adjacent sub-pixels;
wherein reflective layers of the adjacent sub-pixels are continuous to form a general reflective layer, the general reflective layer comprises a first reflective portion located inside an opening region and a second reflective portion located outside the opening region, the second reflective portion comprises a first sub-portion and a second sub-portion located on opposite sides of the first sub-portion, a projection of the first sub-portion on the base substrate at least partially overlaps with a projection of the non-covering portion of the pixel defining layer on the base substrate, and a projection of the second sub-portion on the base substrate at least partially overlaps with a projection of the covering portion of the pixel defining layer on the base substrate; and
wherein a surface of the first sub-portion of the second reflective portion away from the base substrate and a surface of the second sub-portion away from the base substrate have a first height difference, and a surface of the covering portion of the pixel defining layer away from the base substrate and a surface of the non-covering portion of the pixel defining layer away from the base substrate have a second height difference, a difference between the first height difference and the second height difference being within a preset range;
wherein
$$\vert Δ Dpdl - Δ reflect \vert / Δ reflect < 5 \% ,$$
where Δreflect represents the first height difference, and ΔDpdl represents the second height difference.

30. (canceled)

31. The display panel according to claim 29,
wherein the surface of the non-covering portion of the pixel defining layer away from the base substrate is lower than the surface of the covering portion of the pixel defining layer away from the base substrate, and
the surface of the first sub-portion of the second reflective portion away from the base substrate is lower than the surface of the second sub-portion away from the base substrate;
wherein:
a thickness of the first sub-portion is equal to a thickness of the second sub-portion, and a surface of the first sub-portion close to the base substrate is lower than a surface of the second sub-portion close to the base substrate; or
the covering portion of the pixel defining layer has an undercut structure on a side of the covering portion facing the non-covering portion, a thickness of the first sub-portion of the second reflective portion is smaller than a thickness of the second sub-portion of the second reflective portion, and a surface of the first sub-portion close to the base substrate is substantially flush with a surface of the second sub-portion close to the base substrate; or
the surface of the non-covering portion of the pixel defining layer away from the base substrate is lower than a surface of the transparent conductive layer of the first electrode close to the base substrate, the surface of the first sub-portion away from the base substrate is lower than the surface of the second sub-portion away from the base substrate, and a surface of the first sub-portion close to the base substrate is substantially flush with a surface of the second sub-portion close to the base substrate.

32. (canceled)

33. (canceled)

34. (canceled)

35. The display panel according to claim 29,
wherein the surface of the non-covering portion of the pixel defining layer away from the base substrate is higher than the surface of the covering portion of the pixel defining layer away from the base substrate; and
wherein the surface of the first sub-portion of the second reflective portion away from the base substrate is higher than the surface of the second sub-portion away from the base substrate.

36. A display panel, comprising a base substrate and a plurality of sub-pixels disposed on the base substrate, wherein the sub-pixel comprises:
a driving transistor located on the base substrate, the driving transistor having a gate, a source, and a drain;
a light-emitting element located on a side of the driving transistor away from the base substrate, the light-emitting element comprising a first electrode, a second electrode, and a light-emitting material layer between the first electrode and the second electrode, wherein the first electrode is electrically connected to the source or the drain of the driving transistor, and the first electrode has a center region and an edge region surrounding the center region; and
a pixel defining layer covering at least a portion of the edge region of the first electrode,
wherein the first electrode comprises a reflective layer, a transparent conductive layer, and a dielectric layer located between the reflective layer and the transparent conductive layer, the second electrode and a portion of the reflective layer located in the center region form a first optical cavity, and the second electrode and a portion of the reflective layer located in the edge region form a second optical cavity;
wherein output light of the first optical cavity has a first central wavelength λ1, and output light of the second optical cavity has a second central wavelength λ2; and
wherein at least one of the reflective layer, the transparent conductive layer and the dielectric layer has different thicknesses in the center region and in the edge region, such that a relative deviation value |1−λ1/λ2| between the first central wavelength λ1 and the second central wavelength λ2 is less than 5%.

37. The display panel according to claim 36, wherein the pixel defining layer covers the entire edge region of the first electrode, and at least one of the reflective layer, the transparent conductive layer and the dielectric layer has a thickness in the center region different from that in the entire edge region;
wherein:
the reflective layer of the first electrode has a same thickness in the center region and in the edge region, and at least one of the transparent conductive layer and the dielectric layer of the first electrode has different thicknesses in the center region and in the edge region;
and wherein a surface of the second electrode facing the first electrode has a protrusion or a recess, and a projection of the protrusion or the recess on the base substrate at least partially overlaps with a projection of the center region of the first electrode on the base substrate; or
the transparent conductive layer of the first electrode has a same thickness in the center region and in the edge region, and at least one of the reflective layer and the dielectric layer of the first electrode has different thicknesses in the center region and in the edge region;
and wherein a surface of the second electrode facing the first electrode is substantially parallel to the base substrate.

38. (canceled)

39. (canceled)

40. A display device comprising the display panel according to claim 1.
